(19) United States
(12) Patent Application Publication
(10) Pub. No.: US 2024/0321825 A1
(43) Pub. Date: Sep. 26, 2024

(54) FAN-OUT PACKAGING METHOD AND PACKAGING STRUCTURE THEREOF

(71) Applicant: TONGFU MICROELECTRONICS CO., LTD., Nantong (CN)

(72) Inventor: Maohua DU, Nantong (CN)

(21) Appl. No.: 18/680,211

(22) Filed: May 31, 2024

Related U.S. Application Data
(63) Continuation of application No. PCT/CN2022/137251, filed on Dec. 7, 2022.

(30) Foreign Application Priority Data
Dec. 8, 2021 (CN) 202111493898.7
Dec. 8, 2021 (CN) 202111493912.3
Dec. 8, 2021 (CN) 202111493914.2
Dec. 8, 2021 (CN) 202111495849.7
Dec. 8, 2021 (CN) 202111496037.4

(51) Int. Cl. H01L 23/00; H01L 21/56; H01L 23/28

(52) U.S. Cl. CPC H01L 24/96; H01L 21/561; H01L 23/28; H01L 24/19; H01L 24/20; H01L 2224/19; H01L 2224/214; H01L 2224/96

(57) ABSTRACT

A fan-out packaging method and packaging structure are provided. The method includes: providing a wafer carrier, a panel carrier, and groups of first chips; fixing first surfaces of the groups of first chips on the wafer carrier; forming a first plastic encapsulation layer on second surfaces of the groups of first chips; separating the groups of first chips from the wafer carrier; forming a high-density interconnection wiring layer on the first surfaces of the groups of first chips; cutting the groups of first chips; fixing one side of the groups of first chips with the high-density interconnection wiring layer on the panel carrier; forming a second plastic encapsulation layer on another side of the groups of first chips away from the high-density interconnection wiring layer; separating the groups of first chips from the panel carrier; and forming a low-density interconnection wiring layer on the high-density interconnection wiring layer.

### CROSS-REFERENCE TO RELATED APPLICATION

This application is a continuation of International Application No. PCT/CN2022/137251, filed on Dec. 7, 2022, which claims the priority of Chinese Patent Application No. 202111493914.2, filed on Dec. 8, 2021, Chinese Patent Application No. 202111493912.3, filed on Dec. 8, 2021, Chinese Patent Application No. 202111496037.4, filed on Dec. 8, 2021, Chinese Patent Application No. 202111493898.7, filed on Dec. 8, 2021, Chinese Patent Application No. 202111495849.7, filed on Dec. 8, 2021, the contents of which are incorporated herein by reference in their entirety.

### TECHNICAL FIELD

The present disclosure generally relates to the field of semiconductor packaging technology and, more particularly, relates to a fan-out packaging method and a packaging structure.

### BACKGROUND

With development of semiconductor technologies, packaging technology is developing towards high density/high integration. At present, fan-out technology has become an important development direction of high-density interconnection. By using a redistribution layer to connect single-chips or multi-chip, the flexibility of package integration is greatly improved. The fan-out technology has been used in high-performance computing (HPC) and mobile phone processors.

At present, there are two main development directions of the fan-out technology. One is fan-out wafer-level packaging (FOWLP) based on wafer technology, and another is fan-out panel-level packaging (FOPLP) based on panel technology. Wiring density of fan-out wafer-level packaging may be higher, and massive production with a line width of 2 μm has been achieved. However, the yield is low and the cost is high. Although fan-out panel-level packaging has high yield and low cost, it is difficult to achieve thin line widths. Currently, the line widths that can be achieved in massive production are above 5 um.

Also, for multi-chip system-in-package, there are multiple chips in the middle, and the wiring density requirements of each chip are different. A same process is currently used, which requires strictest technical standards and high manufacturing costs.

Therefore, a fan-out packaging method and a packaging structure which are reasonably designed and can effectively solve the above-mentioned problems are necessary.

### SUMMARY

One aspect of the present disclosure provides a fan-out packaging method. The method includes: providing a wafer carrier, a panel carrier, and a plurality of groups of first chips; fixing first surfaces of the plurality of groups of first chips on a surface of the wafer carrier in a form of a first array; forming a first plastic encapsulation layer on second surfaces of the plurality of groups of first chips; separating the plurality of groups of first chips from the wafer carrier; forming a high-density interconnection wiring layer on the first surfaces of the plurality of groups of first chips; cutting the plurality of groups of first chips; fixing one side of the plurality of groups of first chips with the high-density interconnection wiring layer on a surface of the panel carrier; forming a second plastic encapsulation layer on another side of the plurality of groups of first chips away from the high-density interconnection wiring layer; separating the plurality of groups of first chips from the panel carrier; and forming a low-density interconnection wiring layer on the high-density interconnection wiring layer.

Another aspect of the present disclosure provides a fan-out packaging structure. The structure includes: a group of first chips; a high-density interconnection wiring layer; a low-density interconnection wiring layer; a first plastic encapsulation layer; and a second plastic encapsulation layer. The high-density interconnection wiring layer is disposed on the first encapsulation layer and first surfaces of the group of first chips. The low-density interconnection wiring layer is disposed on the high-density interconnection wiring layer. The first plastic encapsulation layer and the second encapsulation layer wrap the group of first chips.

### BRIEF DESCRIPTION OF THE DRAWINGS

The following drawings are merely examples for illustrative purposes according to various disclosed embodiments and are not intended to limit the scope of the present disclosure.

FIG. 1 illustrates an exemplary fan-out packaging method according to various disclosed embodiments of the present disclosure.

FIG. 2 illustrates a schematic chip arrangement area of a wafer carrier according to various disclosed embodiments of the present disclosure.

FIG. 3 illustrates a second array B of a panel carrier according to various disclosed embodiments of the present disclosure.

FIG. 4 illustrates a first array A of a wafer carrier according to various disclosed embodiments of the present disclosure.

FIGS. 5-21 illustrate structures corresponding to certain stages of the fan-out packaging method in FIG. 1.

FIG. 22 illustrates another exemplary fan-out packaging method according to various disclosed embodiments of the present disclosure.

FIG. 23 illustrates a schematic chip arrangement area of a wafer carrier according to various disclosed embodiments of the present disclosure.

FIG. 24 illustrates a second array B of a panel carrier according to various disclosed embodiments of the present disclosure.

FIG. 25 illustrates a first array A of a wafer carrier according to various disclosed embodiments of the present disclosure.

FIGS. 26-38 illustrate structures corresponding to certain stages of a fan-out packaging method according to various disclosed embodiments of the present disclosure.

FIG. 39 illustrates another exemplary fan-out packaging method according to various disclosed embodiments of the present disclosure.

FIG. 40 illustrates a schematic chip arrangement area of a wafer carrier according to various disclosed embodiments of the present disclosure.

FIG. 41 illustrates a second array B of a panel carrier according to various disclosed embodiments of the present disclosure.

FIG. 42 illustrates a first array A of a wafer carrier according to various disclosed embodiments of the present disclosure.

FIGS. 43-56 illustrate structures corresponding to certain stages of a fan-out packaging method according to various disclosed embodiments of the present disclosure.

FIG. 57 illustrates another exemplary fan-out packaging method according to various disclosed embodiments of the present disclosure.

FIG. 58 illustrates a schematic chip arrangement area of a wafer carrier according to various disclosed embodiments of the present disclosure.

FIG. 59 illustrates a second array B of a panel carrier according to various disclosed embodiments of the present disclosure.

FIG. 60 illustrates a first array A of a wafer carrier according to various disclosed embodiments of the present disclosure.

FIGS. 61-75 illustrate structures corresponding to certain stages of a fan-out packaging method according to various disclosed embodiments of the present disclosure.

FIG. 76 illustrates another exemplary fan-out packaging method according to various disclosed embodiments of the present disclosure.

FIG. 77 illustrates a schematic chip arrangement area of a wafer carrier according to various disclosed embodiments of the present disclosure.

FIG. 78 illustrates a second array B of a panel carrier according to various disclosed embodiments of the present disclosure.

FIG. 79 illustrates a first array A of a wafer carrier according to various disclosed embodiments of the present disclosure.

FIGS. 80-95 illustrate structures corresponding to certain stages of a fan-out packaging method according to various disclosed embodiments of the present disclosure.

FIGS. 96-97 illustrate structures corresponding to certain stages of a fan-out packaging method according to various disclosed embodiments of the present disclosure.

FIGS. 98-99 illustrate structures corresponding to certain stages of a fan-out packaging method according to various disclosed embodiments of the present disclosure.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

It should be noted that “surface” or “upper” in this specification are used to describe the relative positional relationship in space, and are not limited to whether they are in direct contact.

The present disclosure provides a packaging method of a fan-out packaging structure.

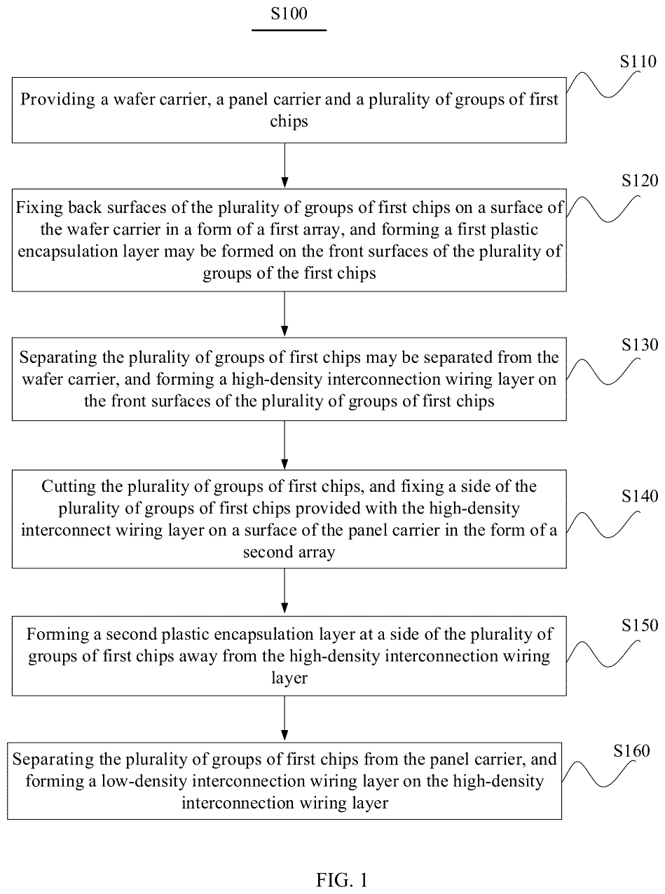

As shown in FIG. 1, one embodiment of the present disclosure provides a packaging method of S100 of a fan-out packaging structure. The packaging method of S100 may include S110 to S160.

In S110, a wafer carrier, a panel carrier and a plurality of groups of first chips may be provided, and a plurality of conductive bumps may be provided on front surfaces of first chips.

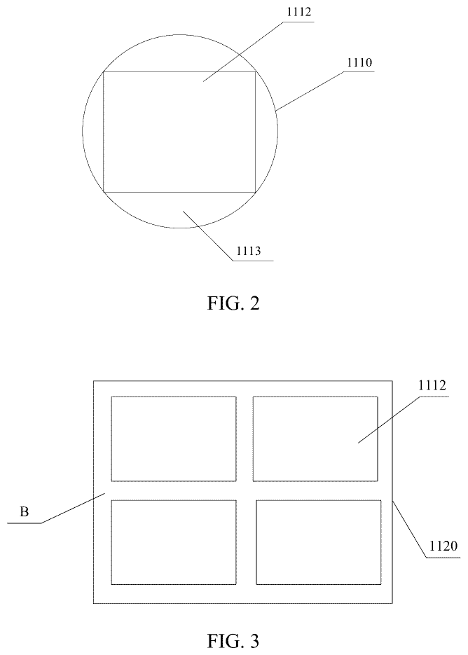

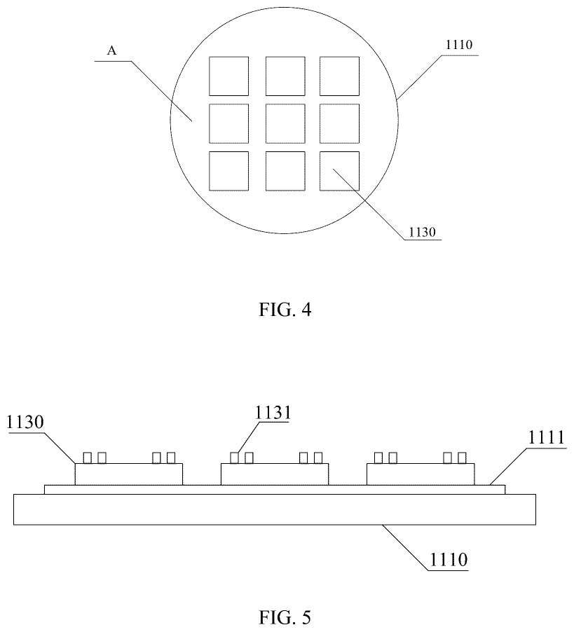

Specifically, as shown in FIG. 2, FIG. 3 and FIG. 4, the wafer carrier 1110, the panel carrier 1120, and the plurality of groups of first chips 1130 may be provided. The plurality of conductive bumps 1131 may be disposed on the front surfaces of the plurality of groups of first chips 1130. In one embodiment, the plurality of conductive bumps 131 may be disposed at two ends of each first chip 1130. The plurality of conductive bumps 1131 may be metal copper conductive bumps or bumps made of other metal materials, which are not specifically limited in this embodiment.

It should be noted that the wafer carrier 1110 may be made of a material including glass, a silicon wafer, or metal. The panel carrier 1120 may be made of a material including glass, metal or glass fiber resin sheet. The materials of the wafer carrier 1110 and the panel carrier 1120 are not specifically limited in this embodiment, and may be selected as required.

In S120, back surfaces of the plurality of groups of first chips may be fixed on a surface of the wafer carrier in a form of a first array, and a first plastic encapsulation layer may be formed on the front surfaces of the plurality of groups of the first chips.

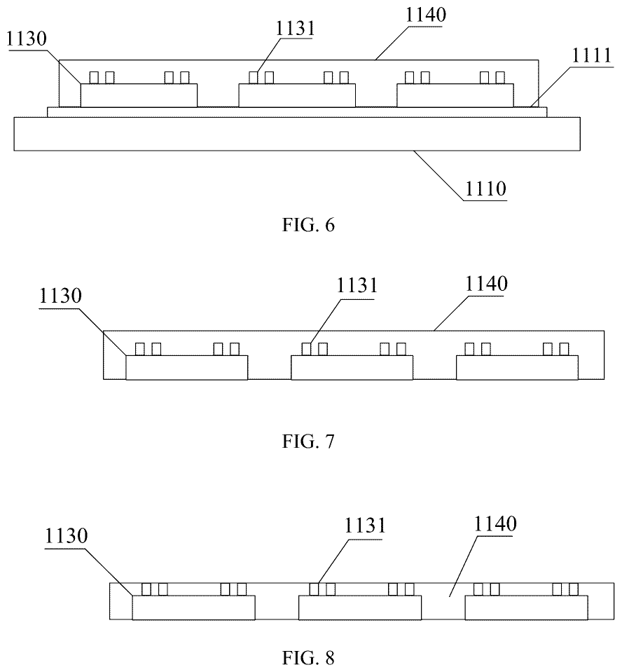

Specifically, as shown in FIG. 5, the back surfaces of the plurality of groups of first chips 1130 may be fixed on the surface of the wafer carrier 1110 through a first patch adhesive 1111. That is, the plurality of groups of first chips 1130 may be fixed on the surface of the wafer carrier 1110 with their front surfaces facing up. Using wafer-level packaging technology, high-density interconnect requirements may be achieved. As shown in FIG. 3, the plurality of groups of first chips 1130 after being fixed may form a first array A, and the first array A may be a square array. As shown in FIG. 6, the front surfaces of the plurality of groups of the first chips 1130 may be plastic-encapsulated to form the first plastic encapsulation layer 1140, and the first plastic-encapsulation layer 1140 may protect the first chips 1130. The plastic-encapsulation method may be vacuum lamination of film layers or traditional plastic-encapsulation process, which is not specifically limited in this embodiment.

It should be noted that each group of first chips 1130 may include one or more first chips 1130. In the present embodiment, each group of first chips may include only one first chip 1130.

In S130, the plurality of groups of first chips may be separated from the wafer carrier, and a high-density interconnection wiring layer may be formed on the front surfaces of the plurality of groups of first chips.

Specifically, as shown in FIG. 7, the back surfaces of the plurality of groups of first chips 1130 may be separated from the wafer carrier 1110, and the separation method may be thermal separation, laser separation, ultraviolet light separation, mechanical separation, etc. All of these methods are temporary bonding separation methods that are commonly used, which are not specifically limited in this embodiment and can be selected according to actual needs.

As shown in FIG. 8, after separating the back surfaces of the plurality of groups of first chips 1130 from the wafer carrier 1110, the front surfaces of the plurality of groups of first chips 1130 may be polished to expose the plurality of conductive bumps 1131 on the front surfaces of the plurality of groups of first chips 1130. In some other embodiments, some other processes may also be used to expose the plurality of conductive bumps 1131, which are not specifically limited in this embodiment.

In one embodiment, the high-density interconnection wiring layers may be formed on the front surfaces of the plurality of groups of first chips by following processes.

A first dielectric layer may be formed on the first plastic encapsulation layer and the plurality of conductive bumps, and the first dielectric layer may be patterned to form a plurality of first openings.

Specifically, as shown in FIG. 9, the first dielectric layer 1150 may be coated on the first plastic encapsulation layer 1140 and the plurality of conductive bumps 1131. The first dielectric layer 1150 may be made of a material including polyimide (PI), polyimide benzoxazole (PBO), etc. The coating method may be usually wafer spin coating, which is not specifically limited in this embodiment. The first dielectric layer 1150 may protect the plurality of groups of the first chips 1130. The material and coating process of the first dielectric layer 1150 are not specifically limited in this embodiment, and can be selected according to actual needs.

As shown in FIG. 9, the first dielectric layer 1150 may be patterned through a photolithography process, to form the plurality of first openings 1151 on the first dielectric layer 1150.

Then, a first metal interconnection layer may be formed on a surface of the patterned first dielectric layer, and the first metal interconnection layer may be patterned to form the high-density interconnection wiring layer. The first metal interconnection may be electrically connected to the plurality of conductive bumps.

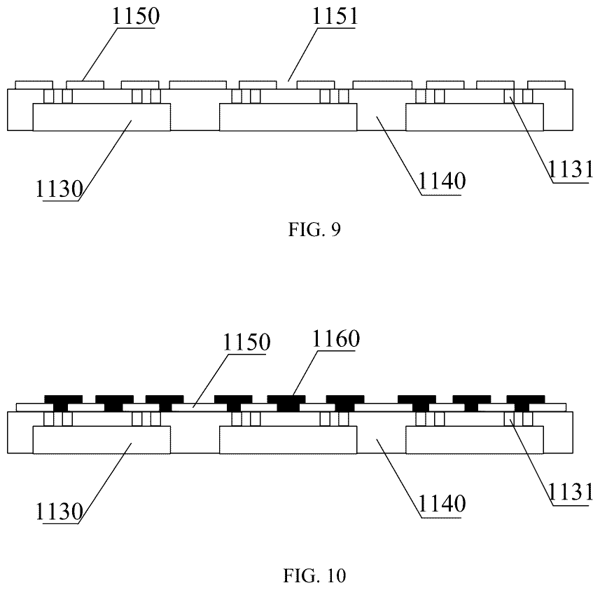

Specifically, as shown in FIG. 10, the first metal interconnection layer 1160 may be deposited on the surface of the patterned first dielectric layer 1150, where the first metal interconnection layer 1160 may be electrically connected to the plurality of conductive bumps 1131. The deposition method may be electroplating, sputtering, thermal evaporation, plasma-enhanced chemical vapor deposition, low-pressure chemical vapor deposition, atmospheric pressure chemical vapor deposition or electron cyclotron resonance chemical vapor deposition, or other processes. The metal material of the first metal interconnection layer 1160 may include usually metal titanium and metal copper. The material and deposition method are not specifically limited in this embodiment. The first metal interconnection layer 1160 may be electrically connected with the plurality of conductive bumps 1131.

As shown in FIG. 10, the first metal interconnection layer 1160 may be patterned through photolithography and etching processes to form the high-density interconnection wiring layer. The etching process may be wet etching or dry etching, which is not specifically limited in this embodiment.

Using fan-out wafer-level packaging to form the above-mentioned high-density interconnection wiring layer may be able to provide a higher interconnection density and meet the requirements of high-performance devices.

In S140, the plurality of groups of first chips may be cut, and a side of the plurality of groups of first chips provided with the high-density interconnect wiring layer may be fixed on a surface of the panel carrier in the form of a second array.

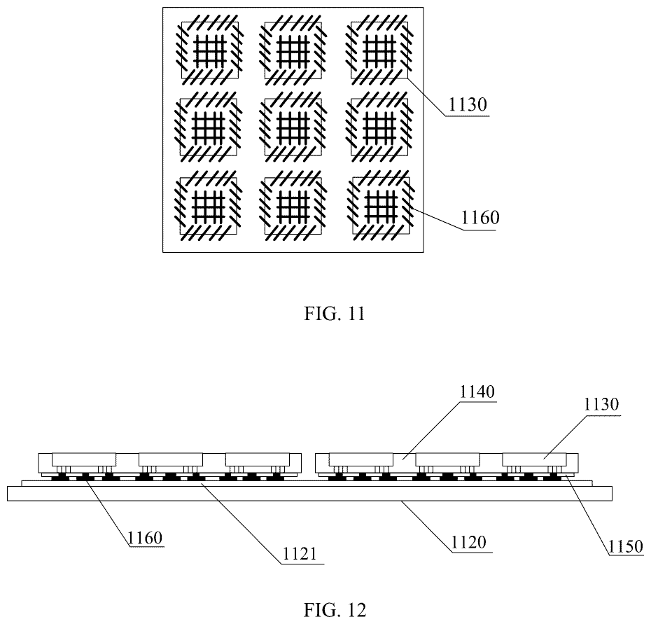

Specifically, as shown in FIG. 11, the plurality of groups of first chips 1130 may be cut according to an area of the panel carrier 1120 and fixed on the surface of the panel carrier 1120 in the form of the second array B shown in FIG. 4. Using the panel-level packaging technology may be able to improve yield and reduce manufacturing costs. In one embodiment, as shown in FIG. 12, the side of the plurality of groups of first chips provided with the high-density interconnection wiring layer may be fixed on the panel carrier 1120 by the second patch adhesive 1121. That is, the first metal interconnection layer 1160 may be bonded to the panel carrier 1120.

In S150, a second plastic encapsulation layer may be formed at a side of the plurality of groups of first chips away from the high-density interconnection wiring layer.

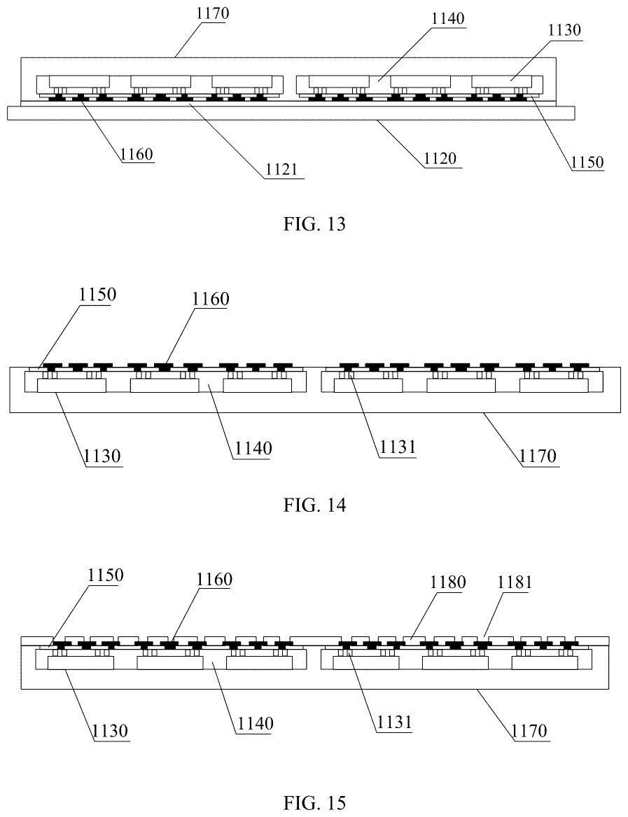

Specifically, as shown in FIG. 13, the plurality of groups of first chips 1130 may be fixed on the panel carrier 1120 in the form of the second array B, and then the second plastic encapsulation layer may be formed at the side of the plurality of groups of first chips 1130 away from the high-density interconnect wiring layer. The plastic encapsulation method may be vacuum lamination of film layers or traditional plastic encapsulation process, which is not specifically limited in this embodiment.

In S160, the plurality of groups of first chips may be separated from the panel carrier, and a low-density interconnection wiring layer may be formed on the high-density interconnection wiring layer.

Specifically, as shown in FIG. 14, the plurality of groups of first chips 1130 may be separated from the panel carrier 1120, and the separation method may include thermal separation, laser separation, ultraviolet light separation, mechanical separation, etc. These methods are all commonly used as temporary bonding separation methods in existing technologies, and are not specifically limited in this embodiment and can be selected according to actual needs.

In one embodiment, the low-density interconnection wiring layer may be formed on the high-density interconnection wiring layer by following processes.

A second dielectric layer may be formed on the surface of the high-density interconnection wiring layer, and the second dielectric layer may be patterned to form a plurality of second openings.

Specifically, as shown in FIG. 15, the second dielectric layer may be formed on the surface of the high-density interconnection wiring layer, that is, the surface of the first metal interconnection layer 1160 may be covered with the second dielectric layer 1180. The second dielectric layer 1180 may protect the first metal interconnection layer 1160. The second dielectric layer 1180 may be made of a material including a photosensitive dielectric layer (PID) or an Ajinomoto laminated film (ABF), etc., which is not specifically limited in this embodiment. The process in which the second dielectric layer 1180 covers the surface of the first metal interconnection layer 1160 may be a vacuum lamination process or a printing process, which is not specifically limited in this embodiment. As shown in FIG. 15, the second dielectric layer 1180 may be patterned through a photolithography process to form the plurality of second openings 1181.

Then, a second metal interconnection layer may be formed on a surface of the patterned second dielectric layer, and the second metal interconnection layer may be patterned to form the low-density interconnection wiring layer.

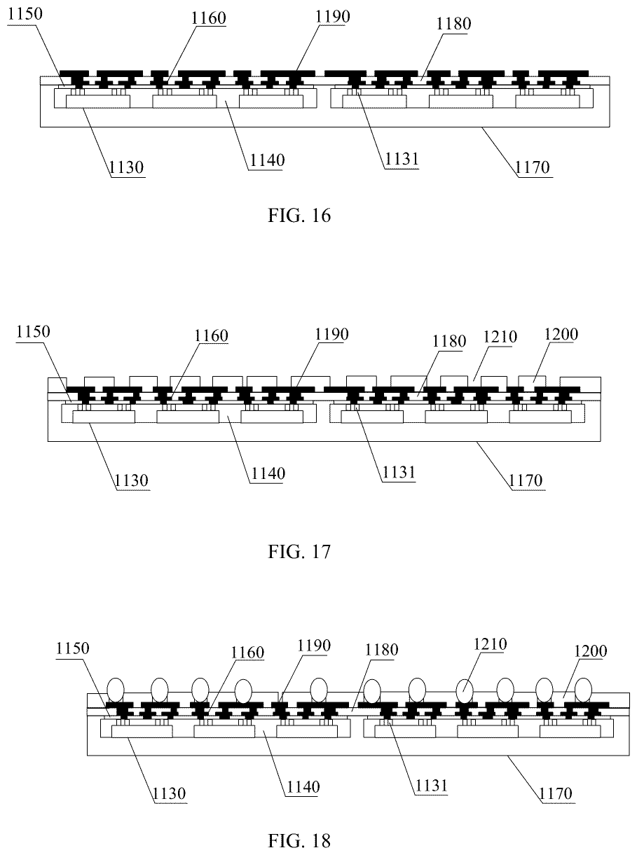

Specifically, as shown in FIG. 16, the second metal interconnection layer 1190 may be deposited on the surface of the patterned second dielectric layer 1180, and the deposition method may be electroplating, sputtering, thermal evaporation, plasma-enhanced chemical vapor deposition, low-pressure Processes such as chemical vapor deposition, atmospheric pressure chemical vapor deposition, or electron cyclotron resonance chemical vapor deposition. The second metal interconnection layer 1190 may be made of a metal material usually including titanium or copper. The deposition method and the metal materials of the second metal interconnection layer 1190 are not specifically limited in this embodiment.

As shown in FIG. 16, the second metal interconnection layer 1190 may be patterned through a photolithography or an etching process to form the low-density interconnection wiring layer. The etching process may be wet etching or dry etching, which is not specifically limited in this embodiment.

As shown in FIG. 16, in one embodiment, the first dielectric layer 1150 and the second dielectric layer 1180 may be made of different dielectric materials. The first dielectric layer 1150 may be made of a material including polyimide (PI), polybenzoxazole (PBO), etc. The second dielectric layer 180 may be made of a material including a photosensitive dielectric layer (PID) or an Ajinomoto laminated film (ABF). The first dielectric layer 1150 may be made by the wafer-level process, and the second dielectric layer 1180 may be made by the panel-level process. The preferred dielectric layers may be selected for different processes and the materials of the two dielectric layers may be close to each other. Problems such as poor contact or unrealizable processes may not appear.

Using the fan-out panel level package to form the above-mentioned low-density interconnection wiring layer may be able to provide lower cost under the condition of the same interconnection density.

In one embodiment, after forming the low-density interconnect wiring layer, the method may further include the following processes.

A third dielectric layer may be formed on the surface of the patterned second metal interconnect layer, and the third dielectric layer may be patterned to form a plurality of third openings.

Specifically, as shown in FIG. 17, the surface of the patterned second metal interconnection layer 1190 may be covered with the third dielectric layer 1200. The third dielectric layer 1200 may be made of a material including photosensitive solder resist (PSR), and there is no specific limitation in this embodiment. The process in which the third dielectric layer 1200 covers the second metal interconnection layer 1190 may be a vacuum lamination process or a printing process, which is not specifically limited in this embodiment. As shown in FIG. 17, the plurality of third openings 1201 may be formed by patterning the third dielectric layer 1200 using a photolithography process.

Then, ball implanting may be performed at the plurality of third openings to form a plurality of solder balls.

Specifically, as shown in FIG. 18, ball implanting may be performed at the plurality of third openings 1201 to form the plurality of solder balls 1210.

Subsequently, the plurality of groups of first chips may be cut to form single-group chip package structures.

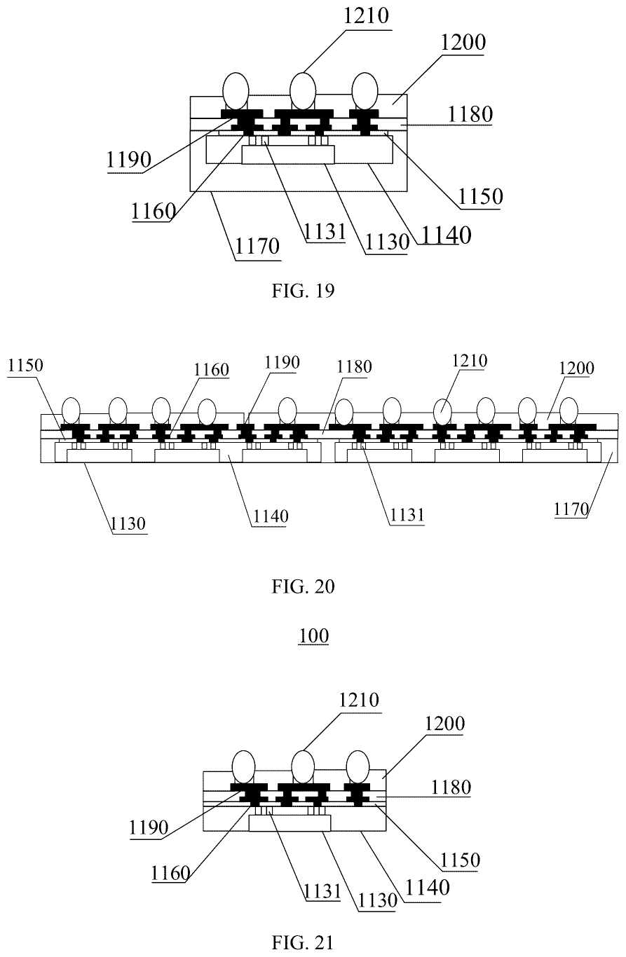

In one embodiment, as shown in FIG. 19, after forming the plurality of solder balls 1210, the plurality of groups of first chips 1130 may be cut to form a single-group chip package structure.

In one embodiment, as shown in FIG. 20, after forming the plurality of solder balls 1210, a side of the second plastic encapsulation layer 1170 away from the plurality of groups of first chips 1130 may be polished to reduce the thickness of the package and finally form the package structure shown in FIG. 21.

In one embodiment, as shown in FIG. 13, after the second plastic encapsulation layer 1170 is formed on one side of the plurality of groups of first chips 1130 facing away from the high-density interconnection wiring layer, a side of the second plastic encapsulation layer 1170 facing away from the plurality of groups of first chips 1130 may be polished to reduce the thickness of the package.

It should be noted that, the above embodiment with a 3-layer or 4-layer dielectric layer structure is used as examples to illustrate the present disclosure, and does not limit the scopes of the present disclosure. In various embodiments, the present disclosure may be applied to a variety of layers, which can be adjusted according to actual design needs. The number of interconnection layers used in the wafer-level and panel-level processes can also be adjusted according to actual design needs. For example, when the second interconnection layer also requires high-density interconnection (which cannot be achieved by panel-level processes), wafer-level processes may be used to form two interconnection layers, which are subsequently transferred to the panel-level process.

In one embodiment, as shown in FIG. 2, the middle area of the wafer carrier 1110 may be chip placement area 1112 and the chip placement area 1112 may be distributed in the first array A as shown in FIG. 3. The chip placement areas 1112 may be a square structure, and may have a diagonal length equivalent to the diameter of the wafer carrier 1110. Through temporary bonding and wafer-level rerouting, the high-density interconnect wiring layer may be formed in the middle area. The chip placement area 1112 having completed the high-density interconnection may be cut and integrally constructed on the panel carrier 1120 in the form of the second array B as shown in FIG. 4.

As shown in FIG. 4, the size of the commonly used panel carrier 1120 may be 510 mm×515 mm. Correspondingly, four chip placement areas 1112 may be disposed at the same time, and the panel level packaging interconnection technology may be used to complete the subsequent process. The production efficiency may be improved and may be able to reach 4 times that of wafer-level packaging technology. When LCD panel technology is used, the production efficiency may be increased by 6-8 times, and the cost may be greatly reduced.

As shown in FIG. 2, since the area of the chip arrangement area 1112 is smaller than that of the wafer carrier 1110, a certain area loss may occur. Considering that the chips are all rectangular or square in size, the main loss area may be the blank area 1113 in the figure, and the size of its short side may be about 28 mm. For samples with a package size close to or larger than 28 mm, this area may be an invalid area. For samples with a package size close to or smaller than 28 mm, the blank area 1113 may still be used. Therefore, the design of chip placement area 1112 may not increase the wafer-level cost of packaging. Since high-density interconnection is mainly used in the fields of high-performance computing and the like, and the packaging in this field is developing in the direction of larger sizes, the present disclosure may significantly reduce the cost.

In the packaging design, an interconnection layer closer to chips may usually have a higher density, while an interconnection layer farther from the chips may have a lower density. The connection line width may show a trend of gradually expanding. Taking advantage of this feature, in the packaging method of the fan-out packaging structure provided by the present disclosure, the fan-out wafer-level packaging technology and the fan-out panel-level packaging technology may be integrated to complete the production of the fan-out packaging. For the interconnection layer closer to the chips, using wafer-level packaging technology may well achieve high-density interconnection requirements. For the interconnection layer farther away from the chips, using panel-level packaging technology may improve yield and reduce manufacturing costs.

The present disclosure also provides a fan-out packaging structure. As shown in FIG. 21, in one embodiment, the fan-out packaging structure 100 may include first chips 1130, a plastic encapsulation layer 1140, a high-density interconnection wiring layer (not shown in the figure), and a low-density interconnection wiring layer (not shown in the figure). A plurality of conductive bumps 1131 may be disposed on front surfaces of the first chips 1130. In this embodiment, the plurality of conductive bumps 1131 may be metal copper conductive bumps. In other embodiments, other metal materials may also be used, which are not specifically limited in this embodiment.

The plastic encapsulation layer 1140 may wrap the plurality of groups of first chips 1130, and the high-density interconnection wiring layer may be sandwiched between the plastic encapsulation layer 1140 and the low-density interconnection wiring layer. The plurality of conductive bumps 1131 and the high-density interconnect wiring layers may be electrically connected.

In one embodiment, as shown in FIG. 21, the high-density interconnection wiring layer may include a first dielectric layer 1150 disposed on the plurality of conductive bumps 1131, and a first metal interconnection layer 1160 on the first dielectric layer 1150. The first metal interconnection layer 1160 may be electrically connected with the plurality of conductive bumps 1131.

The first dielectric layer 1150 may be made of a material including polyimide (PI), or polybenzoxazole (PBO), etc., and may be formed by a coating method usually including wafer spin coating, which is not specifically limited in this embodiment. The first dielectric layer 1150 may protect the plurality of groups of the first chips 1130. The material and coating process of the first dielectric layer 1150 are not specifically limited in this embodiment, and can be selected according to actual needs.

The first metal interconnection layer 1160 may be deposited on the first dielectric layer 1140 by a process including electroplating, sputtering, thermal evaporation, plasma-enhanced chemical vapor deposition, low-pressure chemical vapor deposition, atmospheric pressure chemical vapor deposition, or electron cyclotron resonance chemical vapor deposition. The first metal interconnection layer 1160 may be made of a metal material including titanium or copper. The deposition method and metal material of the first metal interconnection layer 1160 are not specifically limited in this embodiment.

As shown in FIG. 21, the low-density interconnection wiring layer may include a second dielectric layer 1180 disposed on the first metal interconnection layer 1160, and a second metal interconnection layer 1190 on the second dielectric layer 1180.

The second dielectric layer 1180 may be made of a photosensitive dielectric layer (PID) or an Ajinomoto laminated film (ABF), etc., which is not specifically limited in this embodiment. The process in which the second dielectric layer 1180 covers the surface of the first metal interconnection layer 1160 may be a vacuum lamination process or a printing process, which is not specifically limited in this embodiment.

The second metal interconnection layer 1190 may be deposited on the second dielectric layer 1180 by a process including electroplating, sputtering, thermal evaporation, plasma enhanced chemical vapor deposition, low pressure chemical vapor deposition, atmospheric pressure chemical vapor deposition, or electron cyclotron resonance chemical vapor deposition. The second metal interconnection layer 1190 may be made of a metal material including titanium or copper. The deposition method and metal material of the second metal interconnection layer 1190 are not specifically limited in this embodiment.

The first dielectric layer 1150 and the second dielectric layer 1180 may be made of different dielectric materials. The first dielectric layer 1150 may be made of a material including polyimide (PI), polybenzoxazole (PBO), etc. The second dielectric layer 1180 may be made of a material including a photosensitive dielectric layer (PID) or an Ajinomoto laminated film (ABF). The first dielectric layer 1150 may be made by the wafer-level process, and the second dielectric layer 1180 may be made by the panel-level process. The preferred dielectric layers may be selected for different processes and the materials of the two dielectric layers may be close to each other. Problems such as poor contact or unrealizable processes may not appear.

In one embodiment, as shown in FIG. 21, the packaging structure 100 may further include a third dielectric layer 1200 on the second metal interconnect layer 1190 and a plurality of solder balls 1210 on the third dielectric layer 1200.

The third dielectric layer 1200 may be made of a material including photosensitive solder resist (PSR), etc., which is not specifically limited in this embodiment. The process in which the third dielectric layer 1200 covers the second metal interconnection layer 1190 may be a vacuum lamination process or a printing process, which is not specifically limited in this embodiment.

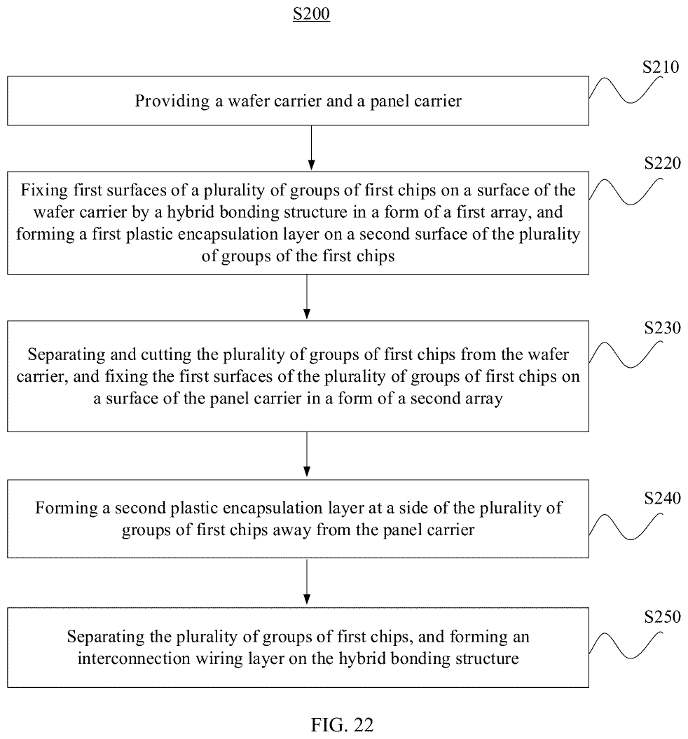

Another embodiment of the present disclosure provides another fan-out packaging method of S200. As shown in FIG. 22, method of S200 may include S210 to S250.

In S210, a wafer carrier and a panel carrier may be provided.

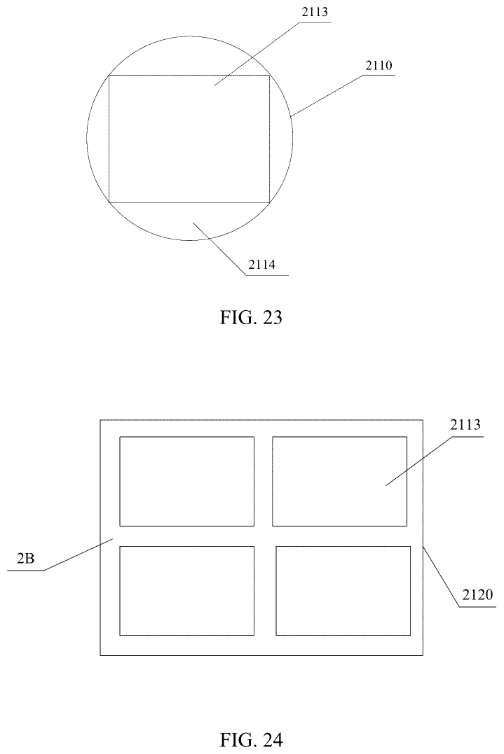

As shown in FIG. 23 to FIG. 25, the wafer carrier 2110 may be made of a material including glass, a silicon wafer or metal. The panel carrier 2120 may be made of a material including glass, metal or glass fiber resin sheet. The materials of the wafer carrier 2110 and the panel carrier 2120 are not specifically limited in this embodiment, and may be selected as required.

In S220, first surfaces of a plurality of groups of first chips may be fixed on a surface of the wafer carrier by a hybrid bonding structure in a form of a first array, and a first plastic encapsulation layer may be formed on a second surface of the plurality of groups of the first chips.

In one embodiment, the hybrid bonding structure may include first passivation layers and first metal pads disposed on the first surfaces of the plurality of groups of first chips, and second passivation layers and second metal pads disposed on a side of the wafer carrier facing the plurality of groups of first chips.

The first passivation layers and the second passivation layers may be connected by hybrid bonding, and the first metal pads and the second metal pads may be connected by hybrid bonding.

Specifically, as shown in FIG. 26, the first passivation layers 2131 and the first metal pads 2132 may be provided on the first surfaces of the plurality of groups of first chips 2130. The second passivation layers 2111 and second metal pads 2112 may be disposed on the side of the wafer carrier 2110 facing the plurality of groups of the first chips 2130. In the present embodiment, the first passivation layers 2131 and the second passivation layers 2111 may be made of a material including silicon dioxide or other materials that can play a passivation role, which are not specifically limited in this embodiment. In this embodiment, the first metal pads 2132 and the second metal pads 2112 may be made of a material including metal copper or other materials, which are not specifically limited in this embodiment.

As shown in FIG. 26, the first surfaces of the plurality of groups of first chips 2130 may be fixed on the surface of the wafer carrier 2110 by hybrid bonding. That is, under the action of heat or pressure, the first passivation layers 2131 on the first surfaces of the plurality of groups of first chips 2130 and the second passivation layers 2111 on the side of the wafer carrier 2110 facing the plurality of groups of first chips 2130 may form bond, and the first metal pads 2132 on the first surface of the plurality of groups of first chips 2130 may be bonded with the second metal pads 2112 on the side of the wafer carrier 2110 facing the plurality of groups of first chips 2130, such that the plurality of groups of first chips 2130 is fixed on the wafer carrier 2110. By means of hybrid bonding, the interconnection density of the first chips may be greatly improved, and the interconnection spacing may be reduced. Using the wafer-level packaging technology may well meet the high-density interconnection requirements and meet the requirements of high-performance devices.

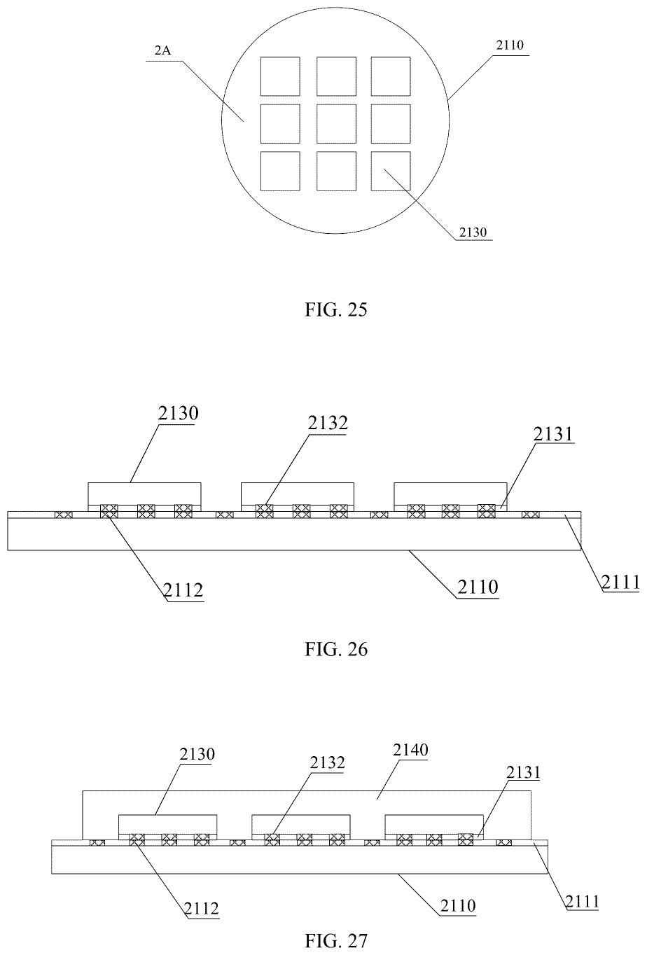

As shown in FIG. 25, the plurality of groups of first chips 2130 after the hybrid bonding may form a first array 2A, and the first array 2A may be a square array. As shown in FIG. 27, the second surfaces of the plurality of groups of first chips 2130 may be encapsulated with a plastic encapsulant to form a first plastic encapsulation layer 2140. The plastic encapsulation method may be vacuum lamination of film layers or traditional plastic encapsulation process, which is not specifically limited in this embodiment.

It should be noted that the first surfaces of the plurality of groups of first chips 2130 may be the front surfaces or the back surfaces of the plurality of groups of first chips 2130. Correspondingly, the second surfaces of the plurality of groups of first chips 2130 may be other sides of the front and back surfaces of the plurality of groups of first chips 2130. In this embodiment, the front surfaces of the plurality of groups of the first chips 2130 may be fixed on the surface of the wafer carrier 2110 by hybrid bonding.

Each group of the plurality of groups of first chips 2130 may include one or more first chips 2130. In one embodiment, group of the plurality of groups of first chips 2130 may include one first chip 2130.

In S230, the plurality of groups of first chips may be separated from the wafer carrier and may be further underwent a cutting process. Then, the first surfaces of the plurality of groups of first chips may be fixed on surface of the panel carrier in a form of a second array.

In one embodiment, separating the plurality of groups of first chips from the wafer carrier may include: removing the wafer carrier by grinding or etching to expose the second passivation layers and the second metal pads.

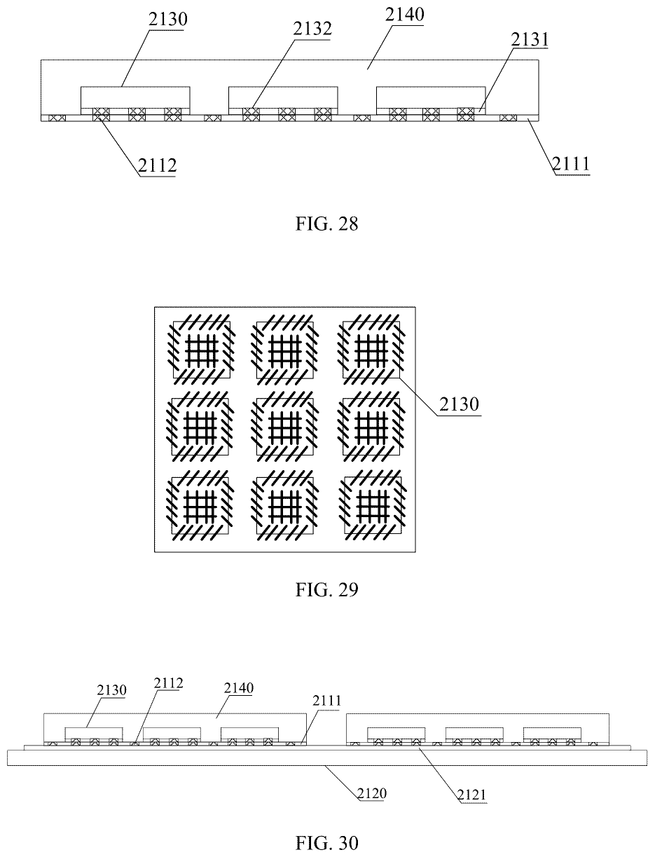

Specifically, as shown in FIG. 28, wafer carrier 2110 may be removed by grinding or etching to expose the second passivation layers 2111 and the second metal pads 2112 on the surface of the wafer carrier 2110, to prepare for the next steps. It should be noted that the etching method may be wet etching or dry etching, which is not specifically limited in this embodiment. Of course, other methods may also be used to remove the wafer carrier 2110, as long as the second passivation layers 2111 and the second metal pads 2112 on the surface of the wafer carrier 110 are exposed.

As shown in FIG. 29 and FIG. 30, the plurality of groups of first chips 2130 may be cut according to the area of the panel carrier 2120.

Then, the plurality of groups of first chips 2130 after cutting may be fixed on the surface of the panel carrier 2120 in the form of the second array 2B shown in FIG. 24. That is, the second metal pads 2112 may be in contact with a second patch adhesive 2121. Panel-level packaging technology may be used to improve yields, and achieve lower costs for the same interconnection density.

In S240, a second plastic encapsulation layer may be formed at a side of the plurality of groups of first chips away from the panel carrier.

Specifically, as shown in FIG. 30, the plurality of groups of first chips 2130 fixed on the panel carrier 2120 may be wrapped with a plastic encapsulation compound to form the second plastic encapsulation layer 2150. The plastic encapsulation method may be vacuum lamination of film layers or traditional plastic encapsulation process, which is not specifically limited in this embodiment.

In S250, the plurality of groups of first chips may be separated from the panel carrier, and an interconnection wiring layer may be formed on the hybrid bonding structure.

As shown in FIG. 32, the panel carrier 2120 and the second patch adhesive 2121 may be separated. The separation method may include thermal separation, laser separation, ultraviolet light separation, mechanical separation, or other methods. These methods are currently commonly used temporary bonding separation methods. The separation method is not specifically limited in this embodiment, and can be selected according to actual needs.

Subsequently, the interconnection wiring layer may be formed on the hybrid bonding structure by: forming a first dielectric layer on the second passivation layers, the second metal pads and the second plastic encapsulation layer; patterning the first dielectric layer to form a plurality of first openings; forming a metal interconnection layer on the surface of the patterned first dielectric layer; and patterning the metal interconnection layer to form the interconnection wiring layer.

Specifically, as shown in FIG. 33, the first dielectric layer 2160 may be coated on the second passivation layers 2111, the second metal pads 2112 and the second plastic encapsulation layer 2150. The first dielectric layer 2160 may be made of a photosensitive dielectric layer (PID) or an Ajinomoto laminated film (ABF), etc., may be formed by a vacuum lamination or printing process. The first dielectric layer 2160 may protect the second passivation layers 2111 and the second metal pads 2112. The material and coating process of the first dielectric layer 2160 are not specifically limited in this embodiment, and can be selected according to actual needs.

The first dielectric layer 2160 may be patterned through a photolithography process, and the plurality of first openings (not marked in the figure) may be formed on the first dielectric layer 2160. The metal interconnect layer 2170 may be deposited on the surface of the patterned first dielectric layer. The deposition method may include electroplating, sputtering, thermal evaporation, plasma enhanced chemical vapor deposition, low pressure chemical vapor deposition, atmospheric pressure chemical vapor deposition or electron cyclotron resonance chemical vapor deposition, etc. The metal materials are usually titanium and copper. The metal material is not specifically limited in this embodiment.

As shown in FIG. 33, the metal interconnection layer 2170 may be patterned through photolithography or etching processes to form the interconnection wiring layer. The etching process may be wet etching or dry etching, which is not specifically limited in this embodiment.

In one embodiment, after forming the interconnect wiring layer, the method may further include: forming a second dielectric layer on the surface of the patterned metal interconnect layer, patterning the second dielectric layer to form a plurality of second openings, and performing ball implanting at the plurality of second openings to form a plurality of solder balls.

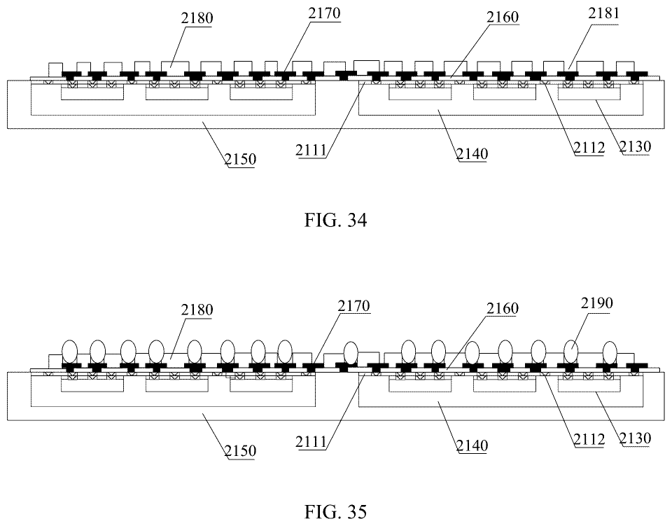

Specifically, as shown in FIG. 34, the second dielectric layer 2180 may be coated on the surface of the patterned metal interconnection layer 2170. The second dielectric layer 2180 may be made of a material including photosensitive solder resist (PSR) and may be formed by a method including vacuum lamination or printing process. The material and coating process of the first dielectric layer 2160 are not specifically limited in this embodiment, and can be selected according to actual needs.

As shown in FIG. 34, the second dielectric layer 2180 may be patterned by a photolithography process, to form the plurality of second openings 2181 on the second dielectric layer 2180.

As shown in FIG. 35, ball implanting may be performed at the plurality of second openings 2181 to form the plurality of solder balls 2190.

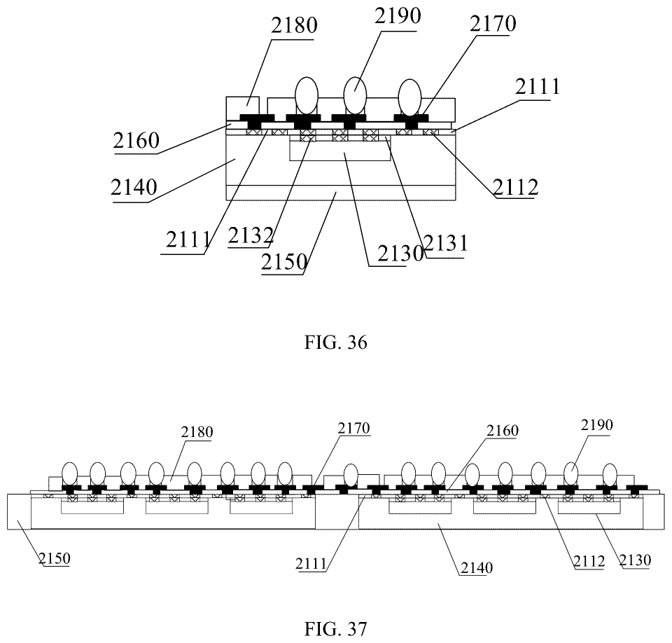

As shown in FIG. 36, after the plurality of solder balls 2190 are formed, the plurality of groups of first chips 2130 may be cut to form single-group chip package structures as shown in the figure.

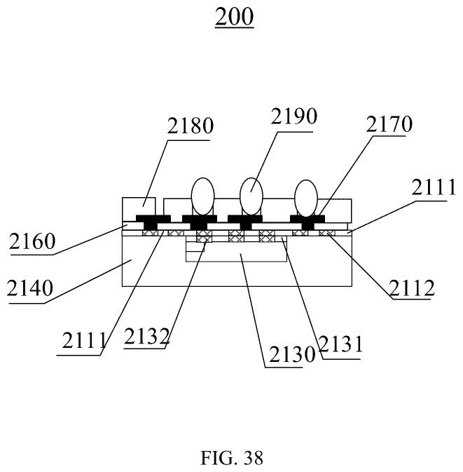

In one embodiment, as shown in FIG. 37, after forming the plurality of solder balls 2190, the side of the second plastic encapsulation layer 2150 away from the plurality of groups of first chips 2130 may be polished to reduce the thickness of the package. In one embodiment, the side of the second plastic encapsulation layer 2150 away from the plurality of groups of first chips 2130 may be completely removed by grinding, and then the package structure shown in FIG. 38 is finally formed by cutting.

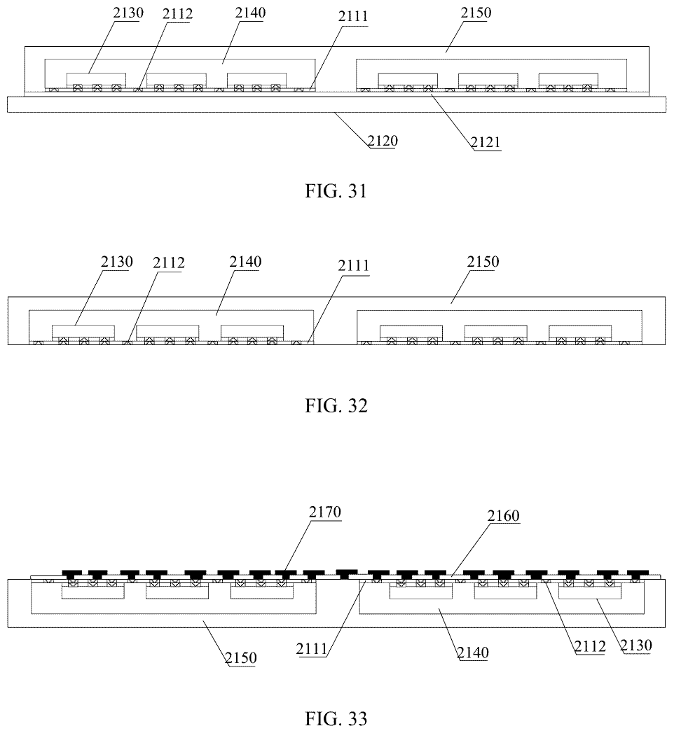

In another embodiment, after the second plastic encapsulation layer is formed on the side of the plurality of groups of first chips away from the panel carrier, the method may further include: as shown in FIG. 31, polishing the side of the second plastic encapsulation layer 2170 away from the plurality of groups of first chips 2130 to reduce the thickness of the package. In one embodiment, the side of the second plastic encapsulation layer 2170 away from the plurality of groups of first chips 2130 may be completely removed by polishing, and then through the above-mentioned various processes, the package structures shown in FIG. 38 may be formed.

As shown in FIG. 38, another embodiment of the present disclosure provides another fan-out packaging structure 200. The packaging structure 200 may include first chips 2130, a hybrid bonding structure (not shown in the figure), an interconnection wiring layer (not shown in the figure) and a plastic encapsulation layer 2140.

The hybrid bonding structure may be disposed on first surfaces of the first chips 2130 and the surface of the plastic encapsulation layer 2140. The interconnection wiring layer may be disposed on the hybrid bonding structure, and the plastic encapsulation layer 2140 may wrap the first surfaces of the first chips 2130.

It should be noted that the first surfaces of the plurality of groups of first chips 2130 may be the front surfaces or the back surfaces of the plurality of groups of first chips 2130. Correspondingly, the second surfaces of the plurality of groups of first chips 2130 may be other sides of the front and back surfaces of the plurality of groups of first chips 2130. In this embodiment, the front surfaces of the plurality of groups of the first chips 2130 may be fixed on the surface of the wafer carrier 2110 by hybrid bonding.

Each group of the plurality of groups of first chips 2130 may include one or more first chips 2130. In one embodiment, group of the plurality of groups of first chips 2130 may include one first chip 2130.

In one embodiment, as shown in FIG. 38, the hybrid bonding structure may include first passivation layers 2131 and first metal pads 2132 disposed on the first surfaces of the first chips 2130, and second passivation layers 2111 and second metal pads 2120 between the plastic encapsulation layer 2140 and the interconnection wiring layer. The first passivation layers 2131 and the second passivation layers 2111 may be connected by hybrid bonding, and the first metal pads 2132 and the second metal pads 2112 may be connected by hybrid bonding. By hybrid bonding, the interconnection density may be greatly increased and the interconnect spacing may be reduced.

In one embodiment, as shown in FIG. 38, the interconnection wiring layer may include a first dielectric layer 2160 disposed on the second passivation layers 2111 and the second metal pads 2112, and a metal interconnection layer 2170 on the first dielectric layer 2160.

The first dielectric layer 2160 may be made of a photosensitive dielectric layer (PID) or an Ajinomoto laminated film (ABF), etc., which is not specifically limited in this embodiment. The metal interconnection layer 2170 may be made of a metal including titanium or copper, which is not specifically limited in this embodiment.

In one embodiment, as shown in FIG. 38, the packaging structure 200 may further include a second dielectric layer 2180 and solder balls 2190. The second dielectric layer 2180 may be disposed on the metal interconnection layer 2170, and the solder balls 2190 may be disposed on the second dielectric layer 2180.

It should be noted that, the above embodiment with a 3-layer or 4-layer dielectric layer structure are used as examples to illustrate the present disclosure, and do not limit the scopes of the present disclosure. In various embodiments, the present disclosure may be applied to a variety of layers, which can be adjusted according to actual design needs. The number of interconnection layers used in the wafer-level and panel-level processes can also be adjusted according to actual design needs. For example, when the second interconnection layer also requires high-density interconnection (which cannot be achieved by panel-level processes), wafer-level processes may be used to form two interconnection layers, which are subsequently transferred to the panel-level process.

In one embodiment, as shown in FIG. 23, the middle area of the wafer carrier 2110 may be chip placement areas 2112 and the chip placement areas 2112 may be distributed in the first array A as shown in FIG. 24. The chip placement areas 2112 may be a square structure, and may have a diagonal length equivalent to the diameter of the wafer carrier 2110. Through temporary bonding and wafer-level rerouting, the high-density interconnect wiring layer may be formed in the middle area. The chip placement area 2112 having completed the high-density interconnection may be cut and integrally constructed on the panel carrier 2120 in the form of the second array B as shown in FIG. 25.

As shown in FIG. 25, the size of the commonly used panel carrier 2120 may be 510 mm×515 mm. Correspondingly, four chip placement areas 2112 may be disposed at the same time, and the panel level packaging interconnection technology may be used to complete the subsequent process. The production efficiency may be improved and may be able to reach 4 times that of wafer-level packaging technology. When LCD panel technology is used, the production efficiency may be increased by 6-8 times, and the cost may be greatly reduced.

As shown in FIG. 23, since the area of the chip arrangement areas 2112 is smaller than that of the wafer carrier 2110, a certain area loss may occur. Considering that the chips are all rectangular or square in size, the main loss area may be the blank area 2113 in the figure, and the size of its short side may be about 28 mm. For samples with a package size close to or larger than 28 mm, this area may be an invalid area. For samples with a package size close to or smaller than 28 mm, the blank area 2113 may still be used. Therefore, the design of the chip placement areas 2112 may not increase the wafer level cost of packaging. Since the high-density interconnection is mainly used in the fields of high-performance computing and the like, and the packaging in this field is developing in the direction of larger sizes, the present disclosure may significantly reduce the cost.

In the packaging design, an interconnection layer closer to chips may usually have a higher density, while an interconnection layer farther from the chips may have a lower density. The connection line width may show a trend of gradually expanding. Taking advantage of this feature, in the packaging method of the fan-out packaging structure provided by the present disclosure, the fan-out wafer-level packaging technology and the fan-out panel-level packaging technology may be integrated to complete the production of the fan-out packaging. For the interconnection layer closer to the chips, using wafer-level packaging technology may well achieve high-density interconnection requirements. For the interconnection layer farther away from the chips, using panel-level packaging technology may improve yield and reduce manufacturing costs.

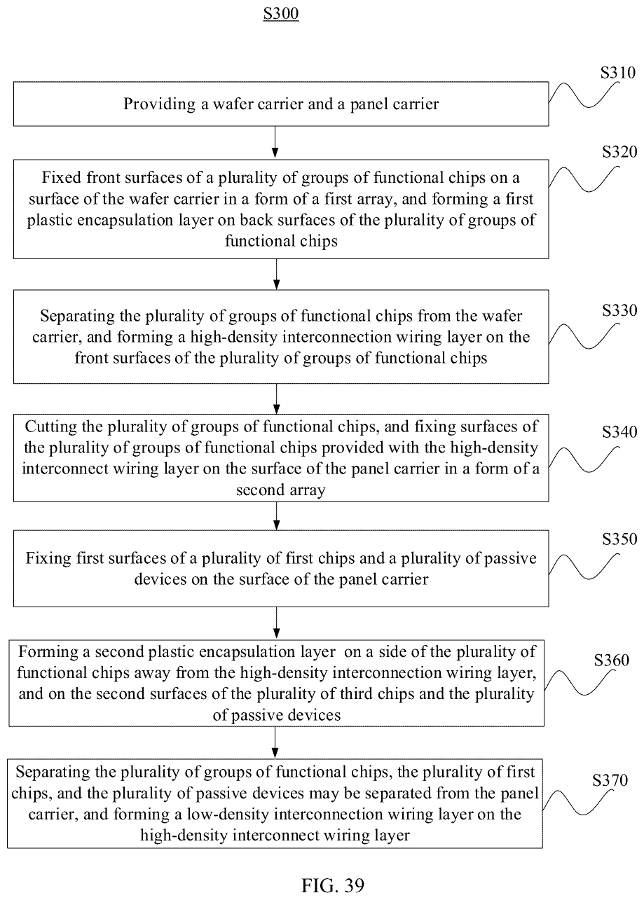

Another embodiment of the present disclosure provides another packaging method of another fan-out packaging structure S300. As shown in FIG. 39, method of S300 may include S310 to S370.

In S310, a wafer carrier and a panel carrier may be provided.

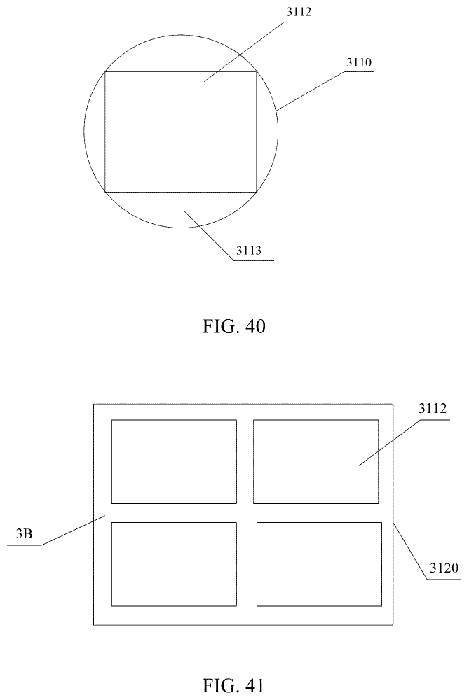

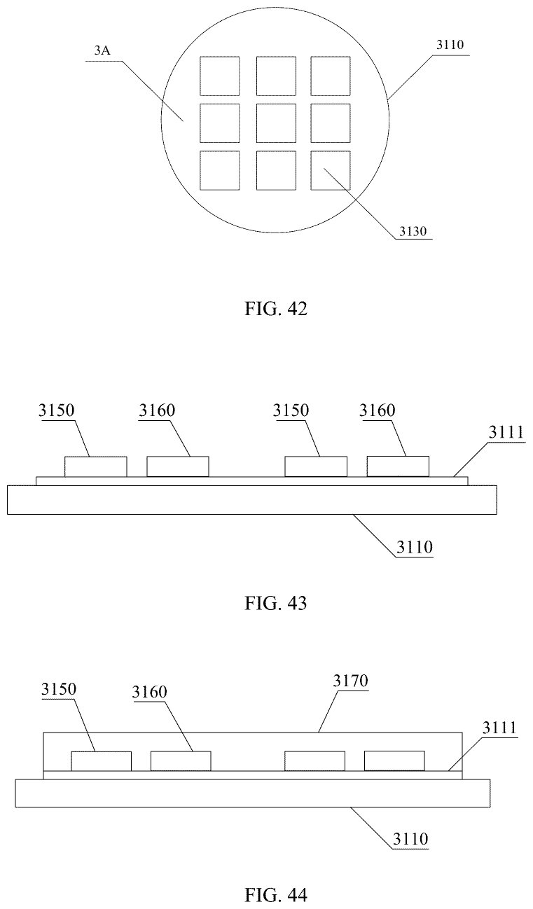

Specifically, as shown in FIG. 40, FIG. 41 and FIG. 42, the wafer carrier 3110 and the panel carrier 3120 may be provided. The wafer carrier 3110 may be made of a material including glass, silicon wafer, or metal. The panel carrier 3120 may be made of a material including glass, metal or glass fiber resin sheet. The materials of the wafer carrier 3110 and the panel carrier 3120 are not specifically limited in this embodiment, and can be selected as required.

A passive device 3140 may be at least one of a resistor, a capacitor, an inductor, a converter, a fader, a matching network, a resonator, a filter, a mixer, or a switch, which is not specifically limited in this embodiment.

In S320, front surfaces of a plurality of groups of functional chips may be fixed on a surface of the wafer carrier in a form of a first array, and a first plastic encapsulation layer may be formed on back surfaces of the plurality of groups of functional chips.

It should be noted that each group of functional chips may include at least two different types of chips. As shown in FIG. 43, in one embodiment, each group of functional chips may include a second chip 3150 and a third chip 3160. The second chip 3150 and the third chip 3160 may be two different types of chips. In one embodiment, the second chip 3150 and the third chip 3160 may be high-performance chips, such as a processor. Of course, each group of functional chips may also include other functional chips, which are not specifically limited in this embodiment.

Specifically, as shown in FIG. 43, in this embodiment, the front surfaces of second chips 3150 and third chips 3160 in the plurality of groups of functional chips may be fixed on the surface of the wafer carrier 3110 by a first batch adhesive 3111. Using wafer-level packaging technology, high-density interconnect requirements may be well achieved. As shown in FIG. 41, the plurality of groups of functional chips after pasting may form a first array 3A, and the first array 3A may be a square array. As shown in FIG. 44, the back surfaces of the plurality of groups of functional chips may be plastic-encapsulated with a plastic encapsulant. That is, the first plastic encapsulation layer 3170 may be formed on the back surfaces of the second chips 3150 and the third chips 3160 in the plurality of groups of functional chips. The plastic encapsulation method may be vacuum lamination of film layers or traditional plastic encapsulation process, which is not specifically limited in this embodiment.

In S330, the plurality of groups of functional chips may be separated from the wafer carrier, and a high-density interconnection wiring layer may be formed on the front surfaces of the plurality of groups of functional chips.

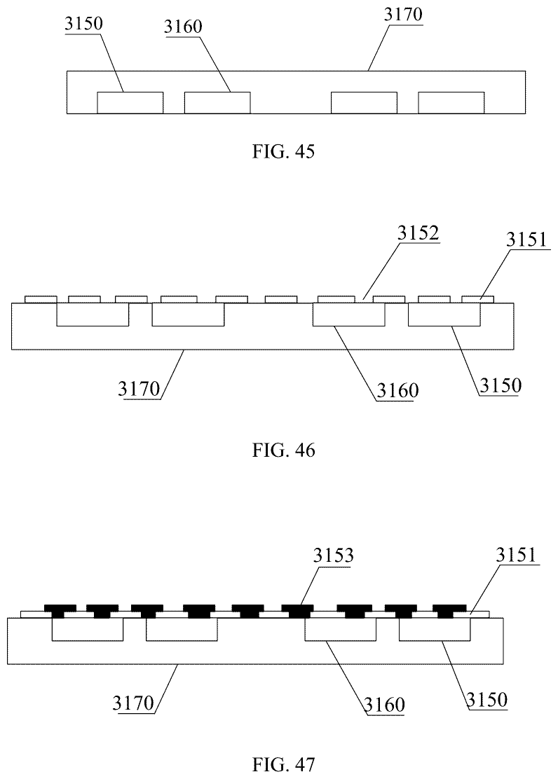

Specifically, as shown in FIG. 45, the plurality of groups of functional chips may be separated from the wafer carrier 3110. That is, the wafer carrier 3110 may be removed. The separation method may be thermal separation, laser separation, ultraviolet light separation, mechanical separation, or other methods. These methods are currently commonly used temporary bonding separation methods. The separation method is not specifically limited in this embodiment, and can be selected according to actual needs.

The high-density interconnection wiring layer may be formed on the front surfaces of the plurality of groups of functional chips by following processes.

First, a first dielectric layer may be formed on the first plastic encapsulation layer and the front surfaces of the plurality of groups of functional chips.

Specifically, as shown in FIG. 46, the first dielectric layer 3151 may be coated on the first plastic encapsulation layer 3170 and the front surfaces of the functional chips in the plurality of groups of functional chips. That is, the first dielectric layer 3151 may be coated on the first plastic encapsulation layer 3170, the surfaces of the second chips 3150, and the surfaces of the third chips 3160. The first dielectric layer 3151 may be made of a material including polyimide (PI), polybenzoxazole (PBO), etc. The coating method may be usually wafer spin coating, which is not specifically limited in this embodiment. The first dielectric layer 3151 may protect the plurality of groups of functional chips.

Subsequently, the first dielectric layer may be patterned to form a plurality of first openings.

As shown in FIG. 46, the first dielectric layer 3151 may be patterned through a photolithography process to form the plurality of first openings 3152.

Then, a first metal interconnection layer may be formed on surface of the patterned first dielectric layer.

Specifically, as shown in FIG. 47, the first metal interconnection layer 3153 may be deposited on the surface of the patterned first dielectric layer 3151. The deposition method may be electroplating, sputtering, thermal evaporation, plasma enhanced chemical vapor deposition, low pressure chemical vapor deposition, atmospheric pressure chemical vapor deposition or electron cyclotron resonance chemical vapor deposition, etc. The first metal interconnection layer 3153 may be usually made of a metal material including metal titanium or metal copper, which is not specifically limited in this embodiment.

The first metal interconnection layer may be patterned to form the high-density interconnection wiring layer.

Specifically, as shown in FIG. 47, the first metal interconnection layer 3153 may be patterned through a photolithography or etching process to form the high-density interconnection wiring layer. The etching process may be wet etching or dry etching, which is not specifically limited in this embodiment.

In this embodiment, the plurality of groups of functional chips may include different types of high-performance chips, such as processor chips. In the system-in-package design, the wiring requirements of high-performance chips are usually high. Therefore, the plurality of groups of functional chips may be packaged using fan-out wafer-level packaging to form the above-mentioned high-density interconnection wiring layer. Higher interconnection density may be provided to meet the needs of high-performance devices.

In S340, the plurality of groups of functional chips may be cut, and surfaces of the plurality of groups of functional chips provided with the high-density interconnect wiring layer may be fixed on the surface of the panel carrier in a form of a second array.

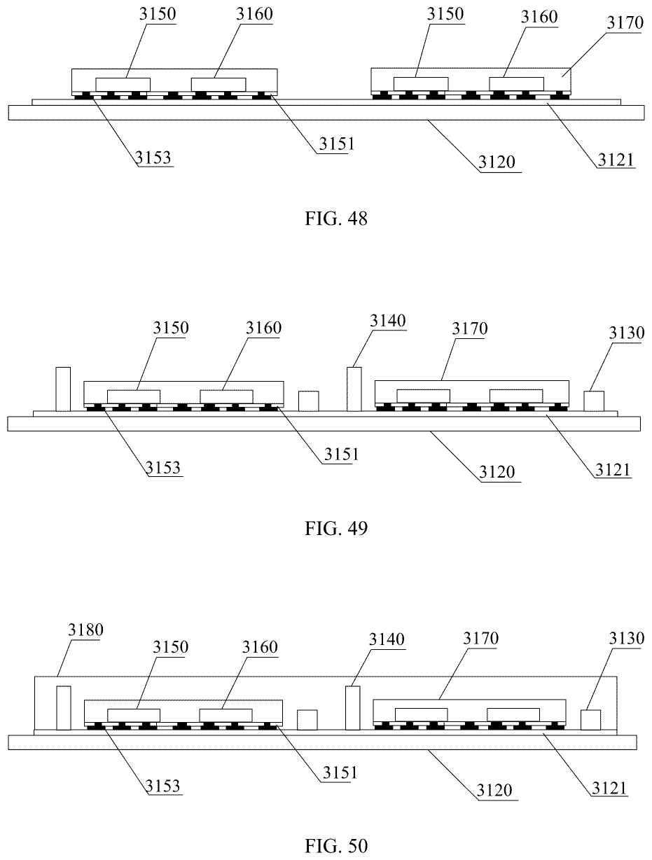

Specifically, according to the area of the panel carrier 3120, the plurality of groups of functional chips may be cut and fixed on the surface of the panel carrier 3120 in the form of the second array 3B shown in FIG. 42. Using the panel level packaging technology may improve the yield and reduce manufacturing costs. In this embodiment, as shown in FIG. 48, the side on which the high-density interconnection wiring layer is formed may be fixed on the panel carrier 3120 by a second patch adhesive 3121. That is, the first metal interconnection layer 3153 may be attached to second patch adhesive 3121.

In S350, first surfaces of a plurality of first chips and a plurality of passive devices may be fixed on the surface of the panel carrier.

It should be noted that, in this embodiment, the plurality of first chips 3130 may be low-performance chips, and may also be other types of chips, which are not specifically limited in this embodiment. The plurality of passive devices 3140 may be at least one of a resistor, a capacitor, an inductor, a converter, a fader, a matching network, a resonator, a filter, a mixer, or a switch, which is not specifically limited in this embodiment.

Specifically, as shown in FIG. 49, the plurality of first chips 3130 and the plurality of passive devices 3140 may be also fixed on the panel carrier 3120 by the second patch adhesive 3121. Further, in one embodiment, the plurality of first chips 3130 and the plurality of passive devices 3140 may be respectively disposed on two sides of each group of functional chips. The plurality of first chips 3130 and the plurality of passive devices 3140 may also be distributed in other manners, which are not specifically limited in this embodiment.

In S360, a second plastic encapsulation layer may be formed on a side of the plurality of functional chips away from the high-density interconnection wiring layer, and on the second surfaces of the plurality of third chips and the plurality of passive devices.

Specifically, as shown in FIG. 50, the plurality of groups of functional chips may be fixed on the panel carrier 3120 in the form of the second array 3B on the side facing away from the high-density interconnection wiring layer, and the second plastic encapsulation layer may be formed on the second surfaces of the plurality of first chips 3130 and the plurality of passive devices 3140. That is, the second plastic encapsulation layer 3180 may encapsulate the plurality of first chips 3130, the plurality of passive devices 3140, the second chips 3150, and the third chips 3160. The plastic encapsulation method may be vacuum lamination of film layers or traditional plastic encapsulation process, which is not specifically limited in this embodiment.

In S370, the plurality of groups of functional chips, the plurality of first chips, and the plurality of passive devices may be separated from the panel carrier, and a low-density interconnection wiring layer may be formed on the high-density interconnect wiring layer.

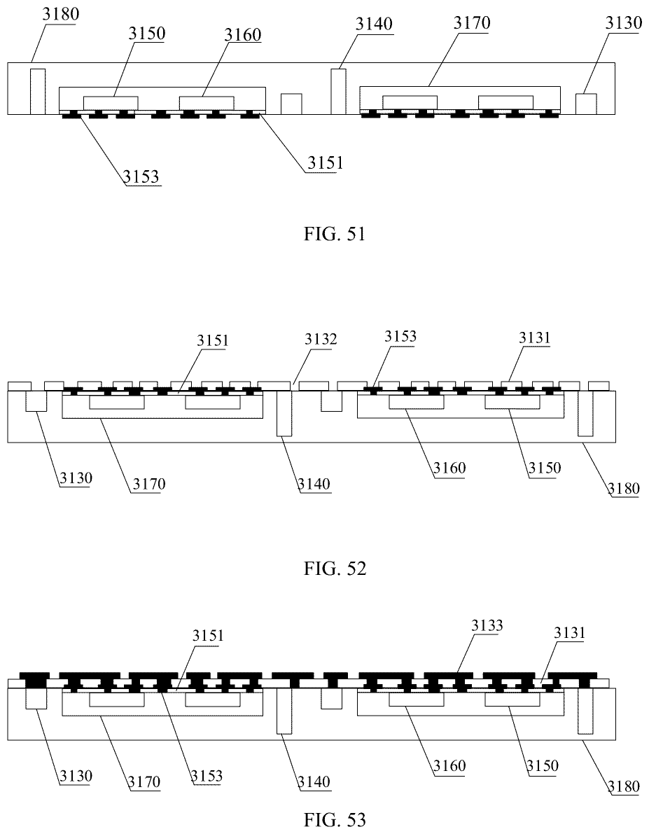

Specifically, as shown in FIG. 51, the plurality of groups of functional chips, the plurality of first chips 3130 and the plurality of passive devices 3140 may be separated from the panel carrier 3120. That is, the panel carrier 3120 may be removed. The separation method may be thermal separation, laser separation, ultraviolet light separation, mechanical separation, or other methods. These methods are currently commonly used temporary bonding separation methods. The separation method is not specifically limited in this embodiment, and can be selected according to actual needs.

The low-density interconnection wiring layer on the high-density interconnection wiring layer may be formed by following processes.

First, a second dielectric layer may be formed on the surface of the high-density interconnection wiring layer and on the first surfaces of the plurality of first chips and the plurality of passive devices.

Specifically, as shown in FIG. 42, the second dielectric layer 3131 may be formed on the first metal interconnection layer 3153, the first surfaces of the plurality of first chips 3130 and the first surfaces of the plurality of passive devices 3140. The second dielectric layer 3131 may protect the first metal interconnection layer 3153. The second dielectric layer 3131 may be made of a material including a photosensitive dielectric layer (PID) or an Ajinomoto laminated film (ABF), etc., which is not specifically limited in this embodiment. The process in which the second dielectric layer 3131 is coated on the first metal interconnection layer 3153, the first surfaces of the plurality of first chips 3130, and the first surfaces of the plurality of passive devices 3140 may be a vacuum lamination or printing process. The present disclosure has no limit on this.

Subsequently, the second dielectric layer may be patterned to form a plurality of second openings.

Specifically, as shown in FIG. 52, the second dielectric layer 3131 may be patterned by a photolithography process, to form the plurality of second openings 3132 on the second dielectric layer 3131.

Then, a second metal interconnection layer may be formed on the surface of the patterned second dielectric layer.

Specifically, as shown in FIG. 53, the second metal interconnection layer 3133 may be deposited on the surface of the patterned second dielectric layer 3131. The deposition method may be electroplating, sputtering, thermal evaporation, plasma enhanced chemical vapor deposition, low pressure chemical vapor deposition, atmospheric pressure chemical vapor deposition or electron cyclotron resonance chemical vapor deposition, etc. The second metal interconnection layer 3133 may be made of a material including metal titanium or metal copper, which is not specifically limited in this embodiment.

Finally, the second metal interconnection layer may be patterned to form the low density interconnection wiring layer.

Specifically, as shown in FIG. 43, the second metal interconnection layer 3133 may be patterned through a photolithography or etching process to form the low-density interconnection wiring layer. The etching process may be wet etching or dry etching, which is not specifically limited in this embodiment.

In this embodiment, the plurality of first chips may include low-performance chips, such as power devices. In the system-in-package design, the low-performance chips usually have low wiring requirements. Therefore, the plurality of first chips and the plurality of passive devices may be packaged using fan-out panel-level packaging to form the low-density interconnection wiring layer, improving the yield and reducing the manufacturing cost.

In one embodiment, the first dielectric layer 3151 and the second dielectric layer 131 may be made of different dielectric materials. The first dielectric layer 3151 may be made of a material including polyimide (PI), polybenzoxazole (PBO), etc. The second dielectric layer 131 may be made of a material including a photosensitive dielectric layer (PID) or an Ajinomoto laminated film (ABF). The first dielectric layer 3151 may be formed by the wafer-level process, and the second dielectric layer 3131 may be formed by the panel-level process. The preferred dielectric layers may be selected for different processes and the materials of the two dielectric layers may be close to each other. Problems such as poor contact or unrealizable processes may not appear.

In one embodiment, after forming the low-density interconnection wiring layer, the method may further include following processes.

First, a third dielectric layer may be formed on the surface of the patterned second metal interconnection layer.

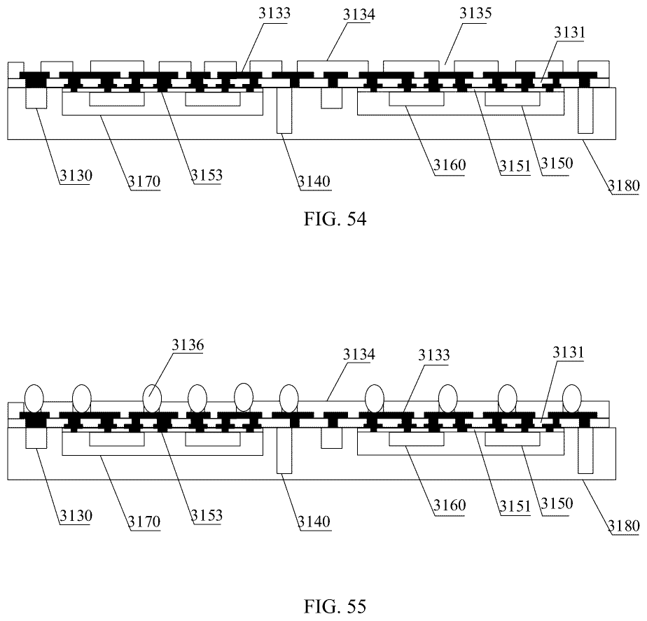

Specifically, as shown in FIG. 54, the surface of the patterned second metal interconnection layer 3133 may be coated with the third dielectric layer 3134. The third dielectric layer 134 may be made of a material including photosensitive solder resist (PSR) or the like, which is no specific limitation in this embodiment. The process of coating the second metal interconnection layer 3133 with the third dielectric layer 3134 may be a vacuum lamination process or a printing process, which is not specifically limited in the present disclosure.

Next, the third dielectric layer may be patterned to form a plurality of third openings.

Specifically, as shown in FIG. 54, the third dielectric layer 3134 may be patterned by a photolithography process, to form the plurality of third openings 3135 on the third dielectric layer 3134.

Finally, ball implanting may be performed at the plurality of third openings to form a plurality of solder balls.

Specifically, as shown in FIG. 55, ball implanting may be performed at the plurality of third openings 3135 to form the plurality of solder balls 3136, and the plurality of solder balls 3136 may be electrically connected to the outside world.

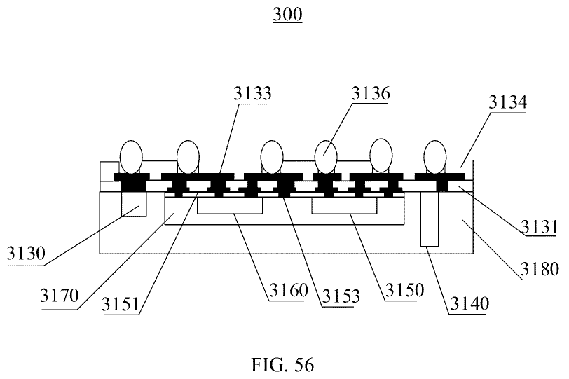

In one embodiment, as shown in FIG. 56, after forming the plurality of solder balls 3136, the plurality of groups of functional chips and the first chips 3130 and passive devices 140 located on two sides of each group of functional chips may be cut to form a single-group chip package structure. Each group chip package structure may include the second chips 3150 and the third chips 3160 located in the middle area, and the first chips 130 and the passive devices 3140 located in the edge area.

It should be noted that, when the thickness of the second plastic encapsulation layer 3180 is very thick, after the plurality of solder balls 3136 are formed, the side of the second plastic encapsulation layer away from the plurality of groups of functional chips may be polished to reduce the thickness of the packaging. In another embodiment, after the second plastic encapsulation layer 3180 is formed, the side of the second plastic encapsulation layer facing away from the plurality of groups of functional chips may be polished to reduce the thickness of the package and form the optimal package structures.

In the fan-out packaging method and packaging structure provided by the present embodiment, the plurality of groups of functional chips may adopt high-density interconnection, which may well meet the requirements of high-density interconnection. The first chips and passive devices may adopt low-density interconnection, which may improve yield and reduce manufacturing cost. By integrating wafer-level fan-out technology and panel-level fan-out technology, different levels of interconnection may be integrated into one package. Compared with the current fan-out wafer-level packaging, the fan-out packaging method of the present embodiment may be able to provide higher interconnection density and meet the requirements of high-performance devices.

It should be noted that, the above embodiment with a 3-layer or 4-layer dielectric layer structure are used as examples to illustrate the present disclosure, and do not limit the scopes of the present disclosure. In various embodiments, the present disclosure may be applied to a variety of layers, which can be adjusted according to actual design needs. The number of interconnection layers used in the wafer-level and panel-level processes can also be adjusted according to actual design needs. For example, when the second interconnection layer also requires high-density interconnection (which cannot be achieved by panel-level processes), wafer-level processes may be used to form two interconnection layers, which are subsequently transferred to the panel-level process.

In one embodiment, as shown in FIG. 40, the middle area of the wafer carrier 3110 may be chip placement areas 3112 and the chip placement areas 3112 may be distributed in the first array 3A as shown in FIG. 41. The chip placement areas 3112 may be a square structure, and may have a diagonal length equivalent to the diameter of the wafer carrier 3110. Through temporary bonding and wafer-level rerouting, the high-density interconnect wiring layer may be formed in the middle area. The chip placement area 3112 having completed the high-density interconnection may be cut and integrally constructed on the panel carrier 3120 in the form of the second array B as shown in FIG. 42.

As shown in FIG. 42, the size of the commonly used panel carrier 3120 may be 510 mm×515 mm. Correspondingly, four chip placement areas 3112 may be disposed at the same time, and the panel level packaging interconnection technology may be used to complete the subsequent process. The production efficiency may be improved and may be able to reach 4 times that of wafer-level packaging technology. When LCD panel technology is used, the production efficiency may be increased by 6-8 times, and the cost may be greatly reduced.

As shown in FIG. 40, since the area of the chip arrangement areas 3112 is smaller than that of the wafer carrier 3110, a certain area loss may occur. Considering that the chips are all rectangular or square in size, the main loss area may be the blank area 3113 in the figure, and the size of its short side may be about 28 mm. For samples with a package size close to or larger than 28 mm, this area may be an invalid area. For samples with a package size close to or smaller than 28 mm, the blank area 3113 may still be used. Therefore, the design of the chip placement areas 3112 may not increase the wafer level cost of packaging. Since the high-density interconnection is mainly used in the fields of high-performance computing and the like, and the packaging in this field is developing in the direction of larger sizes, the present disclosure may significantly reduce the cost.

In the packaging design, an interconnection layer closer to chips may usually have a higher density, while an interconnection layer farther from the chips may have a lower density. The connection line width may show a trend of gradually expanding. Taking advantage of this feature, in the packaging method of the fan-out packaging structure provided by the present disclosure, the fan-out wafer-level packaging technology and the fan-out panel-level packaging technology may be integrated to complete the production of the fan-out packaging. For the interconnection layer closer to the chips, using wafer-level packaging technology may well achieve high-density interconnection requirements. For the interconnection layer farther away from the chips, using panel-level packaging technology may improve yield and reduce manufacturing costs.

Another embodiment of the present disclosure also provides another fan-out packaging structure 300. As shown in FIG. 56, the packaging structure 300 may include: a group of functional chips (not marked in the figure), a first chip 3130, a passive device 3140, a high-density interconnection wiring layer (not marked in the figure), a low-density interconnection wiring layer (not marked in the figure), a first plastic encapsulation layer 3170 and a second plastic encapsulation layer 3180.

It should be noted that the group of functional chips may include at least two different types of chips. As shown in FIG. 56, in this embodiment, the group of functional chips may include a second chip 3150 and a third chip 3160. The second chip 3150 and the third chip 3160 may be different types of chips. In one embodiment, the second chip 3150 and the third chip 3160 may be high-performance chips, such as processors. The group of functional chips may also include other functional chips, which is not specifically limited here. In this embodiment, the first chip 3130 may be a low-performance chip, and may also be other types of chips, which is not specifically limited in this embodiment. The passive device 3140 may be at least one of a resistor, a capacitor, an inductor, a converter, a fader, a matching network, a resonator, a filter, a mixer, or a switch, which is not specifically limited in this embodiment.

As shown in FIG. 56, the high-density interconnection wiring layer may be disposed on the first plastic encapsulation layer 3170 and the front surfaces of the functional chips in the group of functional chips. That is, the high-density interconnect wiring layer may be disposed on the surface of the first plastic encapsulation layer 3170 and the front surfaces of the second chip 3150 and the third chip 3160.

As shown in FIG. 56, the low-density interconnection wiring layer may be disposed on the high-density interconnection wiring layer, and the first surfaces of the first chip 3130 and the passive device 3140. In one embodiment, the first chip 3130 and the passive device 3140 may be respectively disposed at two sides of the group of functional chips.

As shown in FIG. 56, the first plastic encapsulation layer 3170 may wrap the group of functional chips. That is, the first plastic encapsulation layer 3170 may wrap the second chip 3150 and the third chip 3160.

As shown in FIG. 56, the second plastic encapsulation layer 180 may wrap the group of functional chips, the first chip 130 and the passive device 140. That is, the second molding layer 180 may encapsulate the first chip 130, the passive device 140, the second chip 150 and the third chip 160.

In one embodiment, as shown in FIG. 56, the high-density interconnection wiring layer may include a first dielectric layer 3151 disposed on the front surfaces of the functional chips in the group of functional chips, and a first metal interconnection layer 3153 on the first dielectric layer 3151. That is, the front surfaces of the second chip 3150 and the third chip 3160 in each group of functional chips may be provided with the first dielectric layer 3151.

In one embodiment, the low-density interconnect wiring layer may include a second dielectric layer disposed on the first metal interconnection layer 3153 and on the first surfaces of the first chip 3130 and the passive device 3140, and a second metal interconnection layer 3133 disposed on the second dielectric layer 3131.

In one embodiment, the package structure may further include a third dielectric layer 3134 and a plurality of solder balls 3136. The third dielectric layer 3134 may be disposed on the second metal interconnection layer 3133, and the plurality of solder balls 3136 may be disposed on the third dielectric layer 3134.

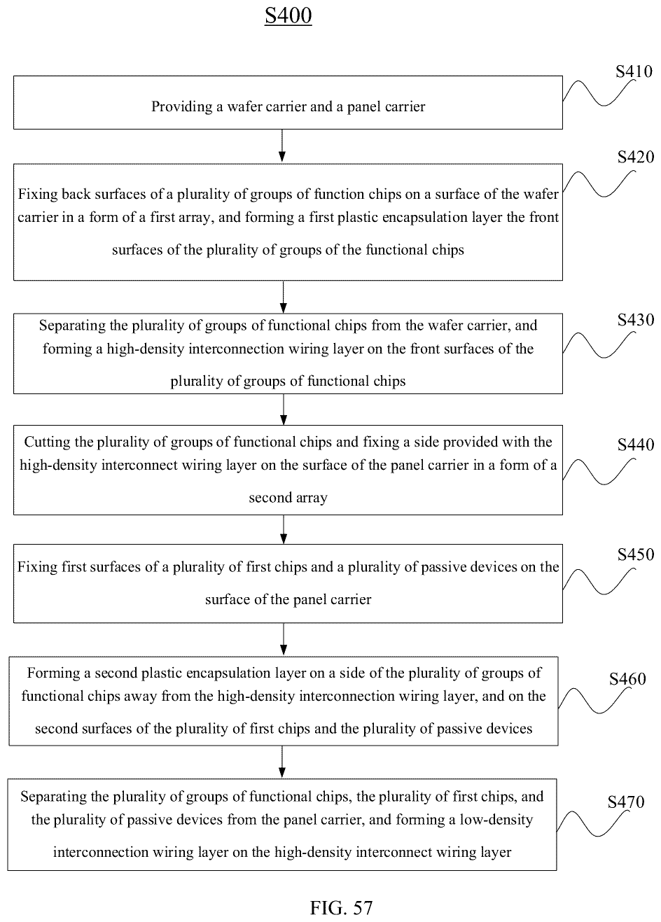

Another embodiment of the present disclosure also provides another packaging method of another fan-out packaging structure S400. As shown in FIG. 57, the packaging method of S400 may include S410 to S460.

In S410, a wafer carrier, a panel carrier and a plurality of groups of first chips may be provided and a plurality of conductive bumps are provided on front surfaces of first chips.

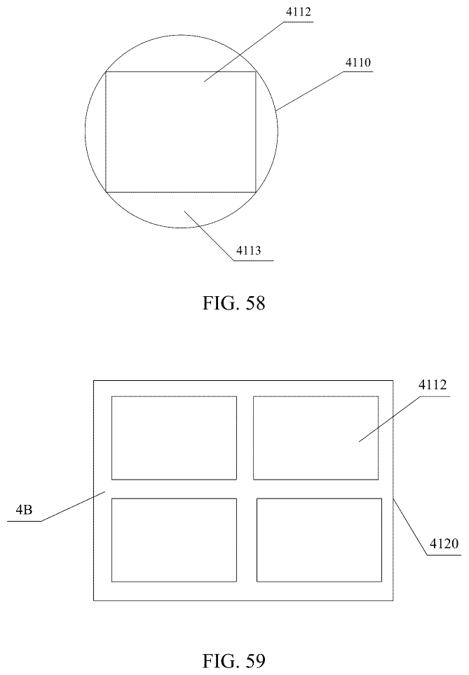

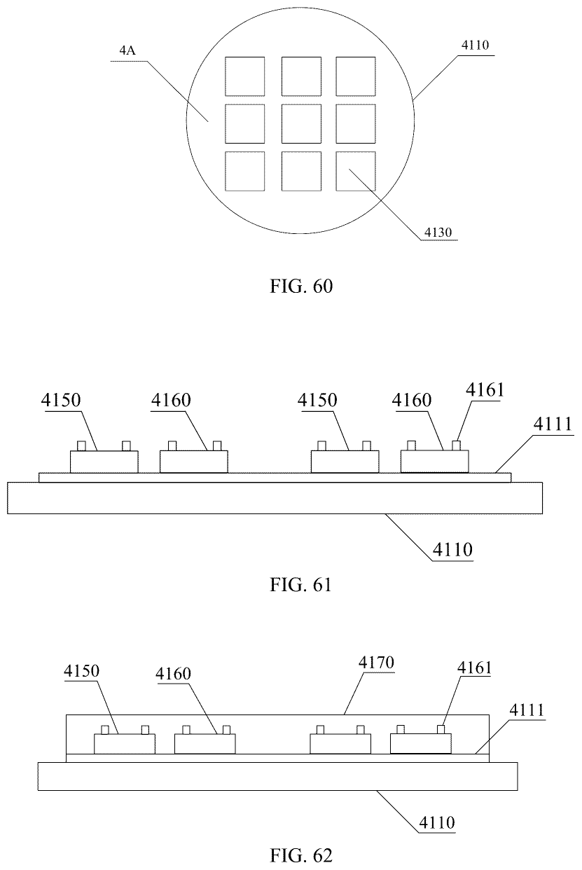

Specifically, as shown in FIG. 58, FIG. 59 and FIG. 60, the wafer carrier 4110 and the panel carrier 4120 may be provided. The wafer carrier 4110 may be made of a material including glass, a silicon wafer or metal. The panel carrier 4120 may be made of a material including glass, metal or glass fiber resin sheet. The materials of the wafer carrier 4110 and the panel carrier 4120 are not specifically limited in this embodiment, and may be selected as required.

In S420, back surfaces of a plurality of groups of function chips may be fixed on a surface of the wafer carrier in a form of a first array, and a first plastic encapsulation layer may be formed on the front surfaces of the plurality of groups of the functional chips. The front surfaces of the plurality of groups of the functional chips may be provided with a plurality of conductive bumps.

It should be noted that each group of functional chips may include at least two different types of chips. As shown in FIG. 61, in one embodiment, each group of functional chips may include a second chip 4150 and a third chip 4160. The second chip 4150 and the third chip 4160 may be two different types of chips. The second chip 4150 and the third chip 4160 may be high-performance chips, such as a processor. Of course, each group of functional chips may also include other functional chips, which are not specifically limited in this embodiment. The plurality of conductive bumps 4161 may be disposed on the front surfaces of the plurality of groups of functional chips. That is, the plurality of conductive bumps 4161 may be provided on the front surfaces of the second chips 4150 and the third chips 4160. In this embodiment, the plurality of conductive bumps 4161 may be respectively disposed at two ends of the second chips 4150 and the third chips 4160, and may be metal copper conductive bumps. Other metal materials may also be used, and the present disclosure has no limit on this.

Specifically, as shown in FIG. 61, in this embodiment, the front surfaces of the second chips 4150 and the third chips 4160 in the plurality of groups of functional chips may be fixed on the surface of the wafer carrier 4110 by a first batch adhesive 4111. Using wafer-level packaging technology, high-density interconnect requirements may be well achieved. As shown in FIG. 59, the plurality of groups of functional chips after pasting may form a first array 4A, and the first array 4A may be a square array. As shown in FIG. 62, the back surfaces of the plurality of groups of functional chips may be plastic-encapsulated with a plastic encapsulant. That is, the first plastic encapsulation layer 4170 may be formed on the back surfaces of the second chips 4150 and the third chips 4160 in the plurality of groups of functional chips. The plastic encapsulation method may be vacuum lamination of film layers or traditional plastic encapsulation process, which is not specifically limited in this embodiment.

In S430, the plurality of groups of functional chips may be separated from the wafer carrier, and a high-density interconnection wiring layer may be formed on the front surfaces of the plurality of groups of functional chips.

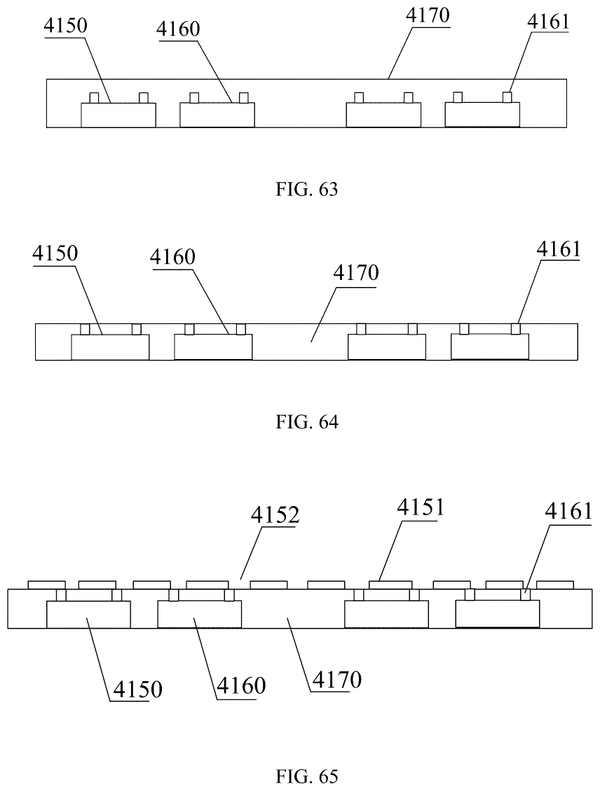

Specifically, as shown in FIG. 63, the plurality of groups of functional chips may be separated from the wafer carrier 4110. That is, the wafer carrier 4110 may be removed. The separation method may be thermal separation, laser separation, ultraviolet light separation, mechanical separation, or other methods. These methods are currently commonly used temporary bonding separation methods. The separation method is not specifically limited in this embodiment, and can be selected according to actual needs.

As shown in FIG. 64, after separating the plurality of groups of functional chips from the wafer carrier 4110, the front surfaces of the plurality of groups of functional chips may be polished. That is, the front surfaces of the second chips 4150 and the third chips 4160 may be polished, to expose the plurality of conductive bumps 4161 on the front surfaces of the second chips 4150 and the third chips 4160. In some other embodiments, some other processes may be used to expose the plurality of conductive bumps 4161 on the front surfaces of the second chips 4150 and the third chips 4160, and the present disclosure has no limit on this.

The high-density interconnection wiring layer may be formed on the front surfaces of the plurality of groups of functional chips by following processes.

First, a first dielectric layer may be formed on the first plastic encapsulation layer and the plurality of conductive bumps.

Specifically, as shown in FIG. 65, the first dielectric layer 4151 may be coated on the first plastic encapsulation layer 4170 and the plurality of conductive bumps 4161. The first dielectric layer 4151 may be made of a material including polyimide (PI), polybenzoxazole (PBO), etc. The coating method may be usually wafer spin coating, which is not specifically limited in this embodiment. The first dielectric layer 4151 may protect the plurality of groups of functional chips.

Subsequently, the first dielectric layer may be patterned to form a plurality of first openings.

As shown in FIG. 65, the first dielectric layer 4151 may be patterned through a photolithography process to form the plurality of first openings 4152.

Then, a first metal interconnection layer may be formed on surface of the patterned first dielectric layer. The first metal interconnection layer may be connected to the plurality of conductive bumps.

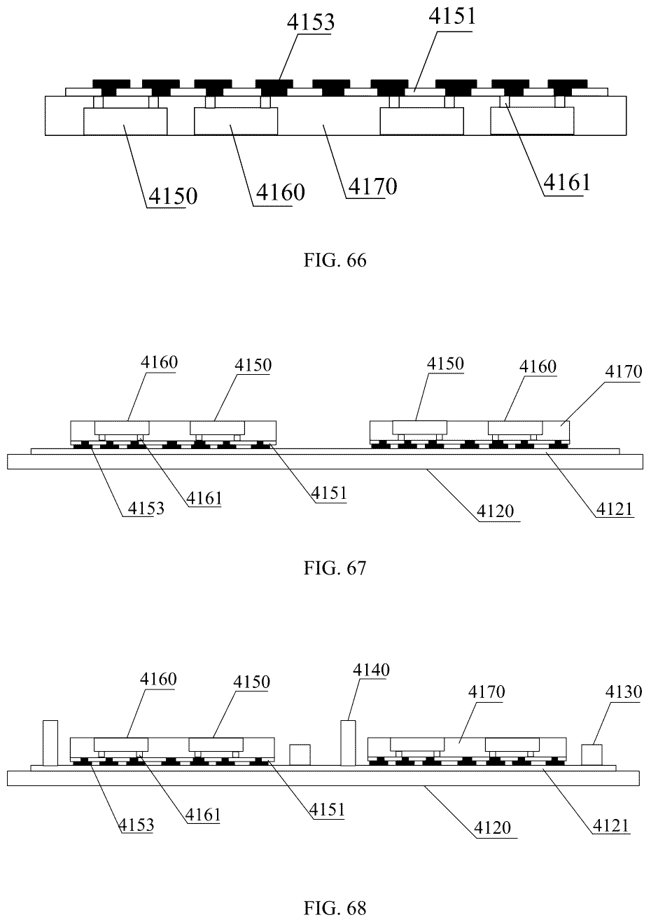

Specifically, as shown in FIG. 66, the first metal interconnection layer 4153 may be deposited on the surface of the patterned first dielectric layer 4151. The deposition method may be electroplating, sputtering, thermal evaporation, plasma enhanced chemical vapor deposition, low pressure chemical vapor deposition, atmospheric pressure chemical vapor deposition or electron cyclotron resonance chemical vapor deposition, etc. The first metal interconnection layer 4153 may be usually made of a metal material including metal titanium or metal copper, which is not specifically limited in this embodiment. The first metal interconnection layer 4153 may be connected to the plurality of conductive bumps 4161.

The first metal interconnection layer may be patterned to form the high-density interconnection wiring layer.

Specifically, as shown in FIG. 66, the first metal interconnection layer 4153 may be patterned through a photolithography or etching process to form the high-density interconnection wiring layer. The etching process may be wet etching or dry etching, which is not specifically limited in this embodiment.

In this embodiment, the plurality of groups of functional chips may include different types of high-performance chips, such as processor chips. In the system-in-package design, the wiring requirements of high-performance chips are usually high. Therefore, the plurality of groups of functional chips may be packaged using fan-out wafer-level packaging to form the above-mentioned high-density interconnection wiring layer. Higher interconnection density may be provided to meet the needs of high-performance devices.

In S440, the plurality of groups of functional chips may be cut, and a side provided with the high-density interconnect wiring layer may be fixed on the surface of the panel carrier in a form of a second array.

Specifically, according to the area of the panel carrier 4120, the plurality of groups of functional chips may be cut and fixed on the surface of the panel carrier 4120 in the form of the second array B shown in FIG. 60. Using the panel level packaging technology may improve the yield and reduce manufacturing costs. In this embodiment, as shown in FIG. 67, the side on which the high-density interconnection wiring layer is formed may be fixed on the panel carrier 4120 by a second patch adhesive 4121. That is, the first metal interconnection layer 4153 may be attached to second patch adhesive 4121.

In S450, first surfaces of a plurality of first chips and a plurality of passive devices may be fixed on the surface of the panel carrier.

It should be noted that, in this embodiment, the plurality of first chips 4130 may be low-performance chips, and may also be other types of chips, which are not specifically limited in this embodiment. The plurality of passive devices 4140 may be at least one of a resistor, a capacitor, an inductor, a converter, a fader, a matching network, a resonator, a filter, a mixer, and a switch, which is not specifically limited in this embodiment.

Specifically, as shown in FIG. 68, the plurality of first chips 4130 and the plurality of passive devices 4140 may be also fixed on the panel carrier 4120 by the second patch adhesive 4121. Further, in one embodiment, the plurality of first chips 4130 and the plurality of passive devices 140 may be respectively disposed on two sides of each group of functional chips. The plurality of first chips 4130 and the plurality of passive devices 140 may also be distributed in other manners, which are not specifically limited in this embodiment.

In S460, a second plastic encapsulation layer may be formed on a side of the plurality of groups of functional chips away from the high-density interconnection wiring layer, and on the second surfaces of the plurality of first chips and the plurality of passive devices.

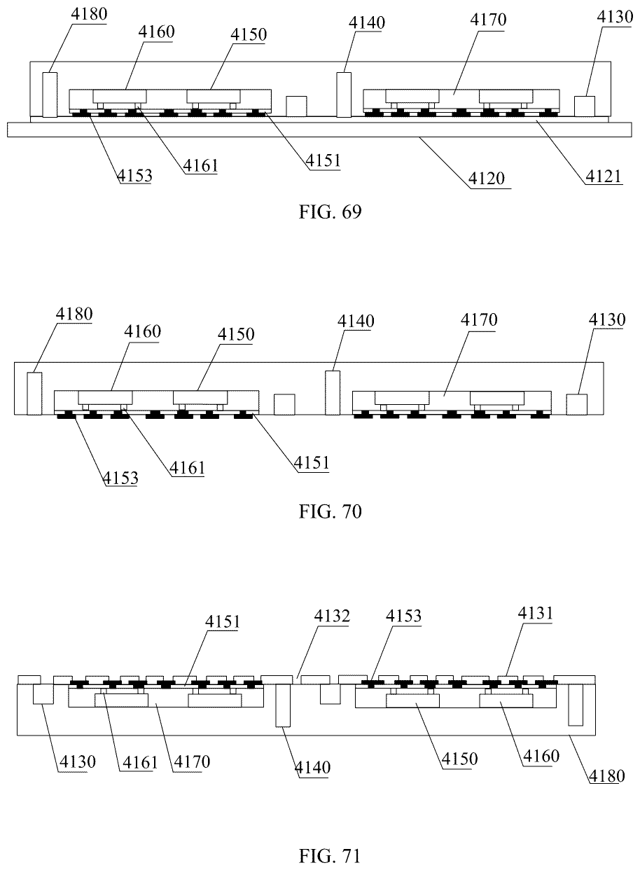

Specifically, as shown in FIG. 69, the plurality of groups of functional chips may be fixed on the panel carrier 4120 in the form of the second array 4B on the side facing away from the high-density interconnection wiring layer, and the second plastic encapsulation layer may be formed on the second surfaces of the plurality of first chips 4130 and the plurality of passive devices 4140. That is, the second plastic encapsulation layer 4180 may encapsulate the plurality of first chips 4130, the plurality of passive devices 4140, the plurality of second chips 4150 and the plurality of third chips 4160. The plastic encapsulation method may be vacuum lamination of film layers or traditional plastic encapsulation process, which is not specifically limited in this embodiment.

In S470, the plurality of groups of functional chips, the plurality of first chips, and the plurality of passive devices may be separated from the panel carrier, and a low-density interconnection wiring layer may be formed on the high-density interconnect wiring layer.

Specifically, as shown in FIG. 70, the plurality of groups of functional chips, the plurality of first chips 4130 and the plurality of passive devices 4140 may be separated from the panel carrier 4120. That is, the panel carrier 4120 may be removed. The separation method may be thermal separation, laser separation, ultraviolet light separation, mechanical separation, or other methods. These methods are currently commonly used temporary bonding separation methods. The separation method is not specifically limited in this embodiment, and can be selected according to actual needs.

The low-density interconnection wiring layer on the high-density interconnection wiring layer may be formed by following processes.

First, a second dielectric layer may be formed on the surface of the high-density interconnection wiring layer and on the first surfaces of the plurality of first chips and the plurality of passive devices.

Specifically, as shown in FIG. 71, the second dielectric layer 4131 may be formed on the first metal interconnection layer 4153, the first surfaces of the plurality of first chips 4130 and the first surfaces of the plurality of passive devices 4140. The second dielectric layer 4131 may protect the first metal interconnection layer 4153. The second dielectric layer 4131 may be made of a material including a photosensitive dielectric layer (PID) or an Ajinomoto laminated film (ABF), etc., which is not specifically limited in this embodiment. The process in which the second dielectric layer 4131 is coated on the first metal interconnection layer 4153, the first surfaces of the plurality of first chips 4130, and the first surfaces of the plurality of passive devices 4140 may be a vacuum lamination or printing process. The present disclosure has no limit on this.

Subsequently, the second dielectric layer may be patterned to form a plurality of second openings.

Specifically, as shown in FIG. 71, the second dielectric layer 4131 may be patterned by a photolithography process, to form the plurality of second openings 4132 on the second dielectric layer 4131.

Then, a second metal interconnection layer may be formed on the surface of the patterned second dielectric layer.

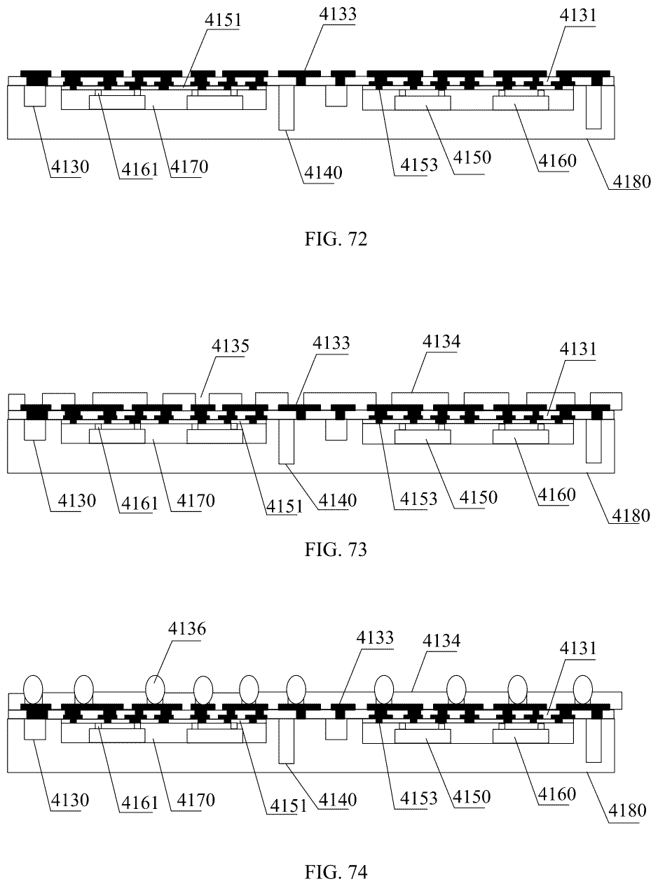

Specifically, as shown in FIG. 72, the second metal interconnection layer 4133 may be deposited on the surface of the patterned second dielectric layer 4131. The deposition method may be electroplating, sputtering, thermal evaporation, plasma enhanced chemical vapor deposition, low pressure chemical vapor deposition, atmospheric pressure chemical vapor deposition or electron cyclotron resonance chemical vapor deposition, etc. The second metal interconnection layer 4133 may be made of a material including metal titanium or metal copper, which is not specifically limited in this embodiment.

Finally, the second metal interconnection layer may be patterned to form the low density interconnection wiring layer.

Specifically, as shown in FIG. 72, the second metal interconnection layer 4133 may be patterned through a photolithography or etching process to form the low-density interconnection wiring layer. The etching process may be wet etching or dry etching, which is not specifically limited in this embodiment.

In this embodiment, the first chips are low-performance chips, such as power devices. In the system-in-package design, the low-performance chips usually have low wiring requirements. Therefore, the plurality of first chips and the plurality of passive devices may be packaged using fan-out panel-level packaging to form the low-density interconnection wiring layer, improving the yield and reducing the manufacturing cost.

In one embodiment, the first dielectric layer 4151 and the second dielectric layer 131 may be made of different dielectric materials. The first dielectric layer 4151 may be made of a material including polyimide (PI), polybenzoxazole (PBO), etc. The second dielectric layer 131 may be made of a material including a photosensitive dielectric layer (PID) or an Ajinomoto laminated film (ABF). The first dielectric layer 4151 may be formed by the wafer-level process, and the second dielectric layer 4131 may be formed by the panel-level process. The preferred dielectric layers may be selected for different processes and the materials of the two dielectric layers may be close to each other. Problems such as poor contact or unrealizable processes may not appear.

In one embodiment, after forming the low-density interconnection wiring layer, the method may further include following processes.

First, a third dielectric layer may be formed on the surface of the patterned second metal interconnection layer.

Specifically, as shown in FIG. 73, the surface of the patterned second metal interconnection layer 4133 may be coated with the third dielectric layer 4134. The third dielectric layer 4134 may be made of a material including photosensitive solder resist (PSR) or the like, which is no specific limitation in this embodiment. The process of coating the second metal interconnection layer 4133 with the third dielectric layer 4134 may be a vacuum lamination process or a printing process, which is not specifically limited in the present disclosure.

Next, the third dielectric layer may be patterned to form a plurality of third openings.

Specifically, as shown in FIG. 73, the third dielectric layer 4134 may be patterned by a photolithography process, to form the plurality of third openings 4135 on the third dielectric layer 4134.

Finally, ball implanting may be performed at the plurality of third openings to form a plurality of solder balls.

Specifically, as shown in FIG. 74, ball implanting may be performed at the plurality of third openings 4135 to form the plurality of solder balls 4136, and the plurality of solder balls 4136 may be electrically connected to the outside world.

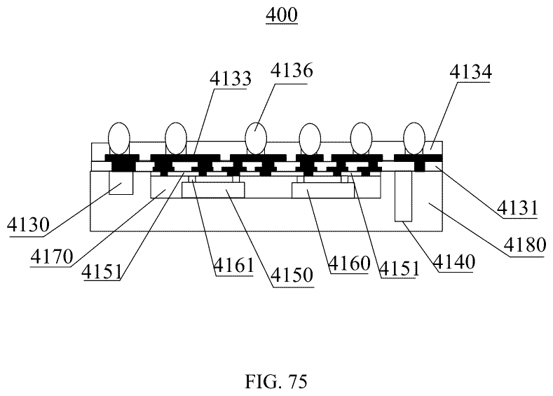

In one embodiment, as shown in FIG. 75, after forming the plurality of solder balls 4136, the plurality of groups of functional chips and the first chips 4130 and passive devices 140 located on two sides of each group of functional chips may be cut to form single-group chip package structures. Each single-group chip package structure may include the second chips 4150 and the third chips 4160 located in the middle area, and the first chips 4130 and the passive devices 140 located in the edge area.

It should be noted that, when the thickness of the second plastic encapsulation layer 4180 is very thick, after the plurality of solder balls 4136 are formed, the side of the second plastic encapsulation layer away from the plurality of groups of functional chips may be polished to reduce the thickness of the packaging. In another embodiment, after the second plastic encapsulation layer 4180 is formed, the side of the second plastic encapsulation layer facing away from the plurality of groups of functional chips may be polished to reduce the thickness of the package and form the optimal package structures.

In the fan-out packaging method and packaging structure provided by the present embodiment, the plurality of groups of functional chips may adopt high-density interconnection, which may well meet the requirements of high-density interconnection. The first chips and passive devices may adopt low-density interconnection, which may improve yield and reduce manufacturing cost. By integrating wafer-level fan-out technology and panel-level fan-out technology, different levels of interconnection may be integrated into one package. Compared with the current fan-out wafer-level packaging, the fan-out packaging method of the present embodiment may be able to provide higher interconnection density and meet the requirements of high-performance devices.

It should be noted that, the above embodiment with a 3-layer or 4-layer dielectric layer structure are used as examples to illustrate the present disclosure, and do not limit the scopes of the present disclosure. In various embodiments, the present disclosure may be applied to a variety of layers, which can be adjusted according to actual design needs. The number of interconnection layers used in the wafer-level and panel-level processes can also be adjusted according to actual design needs. For example, when the second interconnection layer also requires high-density interconnection (which cannot be achieved by panel-level processes), wafer-level processes may be used to form two interconnection layers, which are subsequently transferred to the panel-level process.

In one embodiment, as shown in FIG. 58, the middle area of the wafer carrier 4110 may be chip placement areas 4112 and the chip placement areas 4112 may be distributed in the first array 4A as shown in FIG. 59. The chip placement areas 4112 may be a square structure, and may have a diagonal length equivalent to the diameter of the wafer carrier 4110. Through temporary bonding and wafer-level rerouting, the high-density interconnect wiring layer may be formed in the middle area. The chip placement area 4112 having completed the high-density interconnection may be cut and integrally constructed on the panel carrier 4120 in the form of the second array B as shown in FIG. 60.

As shown in FIG. 60, the size of the commonly used panel carrier 4120 may be 510 mm×515 mm. Correspondingly, four chip placement areas 4112 may be disposed at the same time, and the panel level packaging interconnection technology may be used to complete the subsequent process. The production efficiency may be improved and may be able to reach 4 times that of wafer-level packaging technology. When LCD panel technology is used, the production efficiency may be increased by 6-8 times, and the cost may be greatly reduced.

As shown in FIG. 58, since the area of the chip arrangement areas 4112 is smaller than that of the wafer carrier 4110, a certain area loss may occur. Considering that the chips are all rectangular or square in size, the main loss area may be the blank area 4113 in the figure, and the size of its short side may be about 28 mm. For samples with a package size close to or larger than 28 mm, this area may be an invalid area. For samples with a package size close to or smaller than 28 mm, the blank area 113 may still be used. Therefore, the design of the chip placement areas 112 may not increase the wafer level cost of packaging. Since the high-density interconnection is mainly used in the fields of high-performance computing and the like, and the packaging in this field is developing in the direction of larger sizes, the present disclosure may significantly reduce the cost.

In the packaging design, an interconnection layer closer to chips may usually have a higher density, while an interconnection layer farther from the chips may have a lower density. The connection line width may show a trend of gradually expanding. Taking advantage of this feature, in the packaging method of the fan-out packaging structure provided by the present disclosure, the fan-out wafer-level packaging technology and the fan-out panel-level packaging technology may be integrated to complete the production of the fan-out packaging. For the interconnection layer closer to the chips, using wafer-level packaging technology may well achieve high-density interconnection requirements. For the interconnection layer farther away from the chips, using panel-level packaging technology may improve yield and reduce manufacturing costs.

Another embodiment of the present disclosure also provides another fan-out packaging structure 400. As shown in FIG. 75, the packaging structure 400 may include: a group of functional chips (not marked in the figure), a first chip 4130, a passive device 4140, a high-density interconnection wiring layer (not marked in the figure), a low-density interconnection wiring layer (not marked in the figure), a first plastic encapsulation layer 4170 and a second plastic encapsulation layer 4180. Front surfaces of functional chips in the plurality of groups of functional chips may be provided with conductive bumps 4161.

It should be noted that the group of functional chips may include at least two different types of chips. As shown in FIG. 75, in this embodiment, the group of functional chips may include a second chip 4150 and a third chip 4160. The second chip 4150 and the third chip 160 may be different types of chips. In one embodiment, the second chip 4150 and the third chip 4160 may be high-performance chips, such as processors. The group of functional chips may also include other functional chips, which is not specifically limited here. Front surfaces of functional chips in the plurality of groups of functional chips may be provided with conductive bumps 4161. That is, the front surfaces of the second chip 4150 and the third chip 4160 may be provided with the conductive bumps 4161.

In this embodiment, the first chip 4130 may be a low-performance chip, and may also be other types of chips, which is not specifically limited in this embodiment. The passive device 4140 may be at least one of a resistor, a capacitor, an inductor, a converter, a fader, a matching network, a resonator, a filter, a mixer, or a switch, which is not specifically limited in this embodiment.

As shown in FIG. 75, the high-density interconnection wiring layer may be disposed on the first plastic encapsulation layer 4170 and the front surfaces of the functional chips in the group of functional chips. That is, the high-density interconnect wiring layer may be disposed on the surface of the first plastic encapsulation layer 4170 and the front surfaces of the second chip 4150 and the third chip 4160. Further, the high-density interconnect wiring layer may be disposed on the surface of the first plastic encapsulation layer 4170 and the conductive bumps 4161.

As shown in FIG. 75, the low-density interconnection wiring layer may be disposed on the high-density interconnection wiring layer, and the first surfaces of the first chip 5130 and the passive device 5140. In one embodiment, the first chip 5130 and the passive device 5140 may respectively be disposed at two sides of the group of functional chips.

As shown in FIG. 75, the first plastic encapsulation layer 5170 may wrap the group of functional chips. That is, the first plastic encapsulation layer 5170 may wrap the second chip 150 and the third chip 5160.

As shown in FIG. 75, the second plastic encapsulation layer 5180 may wrap the group of functional chips, the first chip 5130 and the passive device 4140. That is, the second molding layer 4180 may encapsulate the first chip 4130, the passive device 4140, the second chip 4150 and the third chip 4160.

In one embodiment, as shown in FIG. 75, the high-density interconnection wiring layer may include a first dielectric layer 4151 disposed on the front surfaces of the functional chips in the group of functional chips, and a first metal interconnection layer 4153 on the first dielectric layer 4151. That is, the front surfaces of the second chip 4150 and the third chip 4160 in each group of functional chips may be provided with the first dielectric layer 4151.

In one embodiment, the low-density interconnect wiring layer may include a second dielectric layer disposed on the first metal interconnection layer 4153 and on the first surfaces of the first chip 4130 and the passive device 4140, and a second metal interconnection layer 4133 disposed on the second dielectric layer 4131.

In one embodiment, the package structure may further include a third dielectric layer 4134 and a plurality of solder balls 4136. The third dielectric layer 4134 may be disposed on the second metal interconnection layer 4133, and the plurality of solder balls 4136 may be disposed on the third dielectric layer 4134.

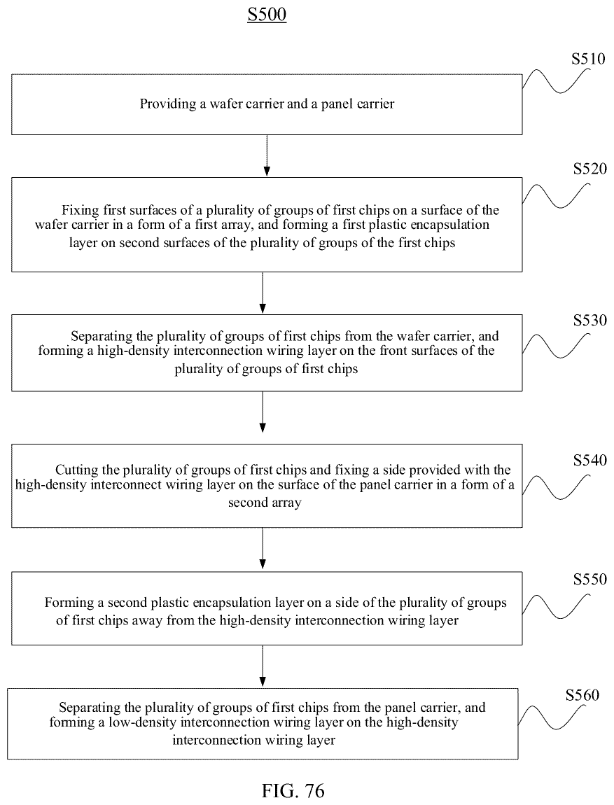

Another embodiment of the present disclosure also provides another packaging method of another fan-out packaging structure S500. As shown in FIG. 76, the packaging method of S500 may include S510 to S560.

In S510, a wafer carrier, a panel carrier and a plurality of groups of first chips may be provided.

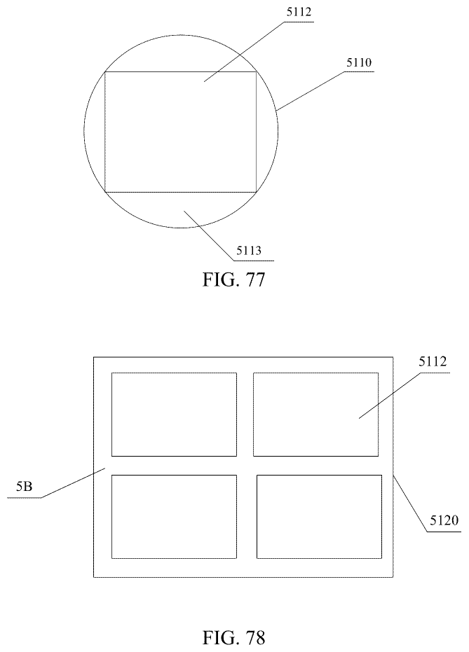

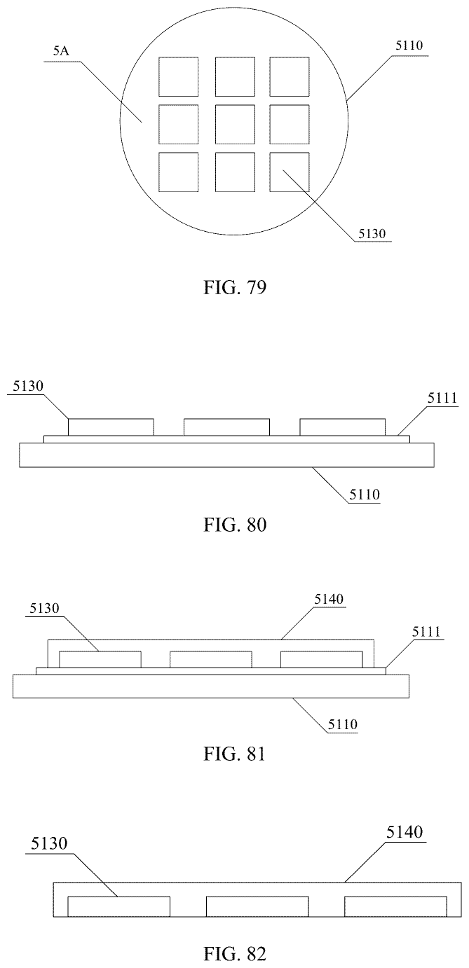

Specifically, as shown in FIG. 77, FIG. 78 and FIG. 79, the wafer carrier 5110 and the panel carrier 5120 may be provided. The wafer carrier 5110 may be made of a material including glass, a silicon wafer or metal. The panel carrier 5120 may be made of a material including glass, metal or glass fiber resin sheet. The materials of the wafer carrier 5110 and the panel carrier 5120 are not specifically limited in this embodiment, and may be selected as required.

In S520, first surfaces of a plurality of groups of first chips may be fixed on a surface of the wafer carrier in a form of a first array, and a first plastic encapsulation layer may be formed on second surfaces of the plurality of groups of the first chips.

Specifically, as shown in FIG. 80, in this embodiment, the first surfaces of the plurality of groups of first chips may be fixed on the surface of the wafer carrier 5110 by a first batch adhesive 5111. Using wafer-level packaging technology, high-density interconnect requirements may be well achieved. As shown in FIG. 78, the plurality of groups of first chips after pasting may form a first array 5A, and the first array 5A may be a square array. As shown in FIG. 81, the second surfaces of the plurality of groups of first chips may be plastic-encapsulated with a plastic encapsulant, to form the first plastic encapsulation layer 5140. The plastic encapsulation method may be vacuum lamination of film layers or traditional plastic encapsulation process, which is not specifically limited in this embodiment.

The first surfaces of the plurality of groups of first chips may be ones of front surfaces or back surfaces of the plurality of groups of first chips, and the second surfaces of the plurality of groups of first chips may be other ones of the front surfaces and back surfaces of the plurality of groups of first chips. In one embodiment, the front surfaces of the plurality of groups of first chips 5130 may be fixed on the surface of the wafer carrier 5110 through the patch adhesive 5111.

Each group of first chips 130 may include one or more first chips 5130.

In S530, the plurality of groups of first chips may be separated from the wafer carrier, and a high-density interconnection wiring layer may be formed on the front surfaces of the plurality of groups of first chips.

Specifically, as shown in FIG. 81 and FIG. 82, the plurality of groups of first chips 5130 may be separated from the wafer carrier 5110. That is, the wafer carrier 5110 may be removed. The separation method may be thermal separation, laser separation, ultraviolet light separation, mechanical separation, or other methods. These methods are currently commonly used temporary bonding separation methods. The separation method is not specifically limited in this embodiment, and can be selected according to actual needs.

The high-density interconnection wiring layer may be formed on the front surfaces of the plurality of groups of first chips by following processes.

First, a first dielectric layer may be formed on the first plastic encapsulation layer and the plurality of groups of first chips, and the first dielectric layer may be patterned to form a plurality of first openings.

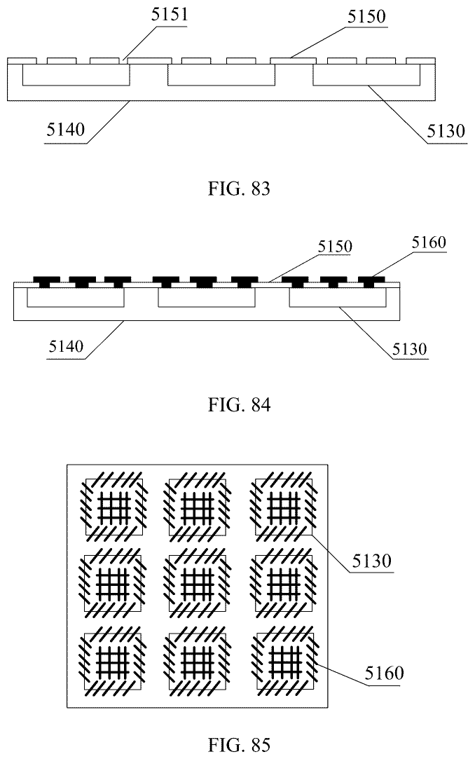

Specifically, as shown in FIG. 83, the first dielectric layer 5150 may be coated on the first plastic encapsulation layer 5140 and the plurality of groups of first chips 5130. The first dielectric layer 5150 may be made of a material including polyimide (PI), polybenzoxazole (PBO), etc. The coating method may be usually wafer spin coating, which is not specifically limited in this embodiment. The first dielectric layer 5150 may protect the plurality of groups of first chips. As shown in FIG. 84, the first dielectric layer 5150 may be patterned through a photolithography process to form the plurality of first openings 5151.

Then, a first metal interconnection layer may be formed on a surface of the patterned first dielectric layer. The first metal interconnection layer may be patterned to form the high-density interconnection wiring layer.

Specifically, as shown in FIG. 84, the first metal interconnection layer 5160 may be deposited on the surface of the patterned first dielectric layer 5150. The deposition method may be electroplating or sputtering. The first metal interconnection layer 5160 may be usually made of a metal material including metal titanium or metal copper, which is not specifically limited in this embodiment. The first metal interconnection layer 5160 may be patterned through a photolithography or etching process to form the high-density interconnection wiring layer. The etching process may be wet etching or dry etching, which is not specifically limited in this embodiment.

In this embodiment, the fan-out wafer-level packaging may be used to form the above-mentioned high-density interconnection wiring layer. Higher interconnection density may be provided to meet the needs of high-performance devices.

In S540, the plurality of groups of first chips may be cut, and a side provided with the high-density interconnect wiring layer may be fixed on the surface of the panel carrier in a form of a second array.

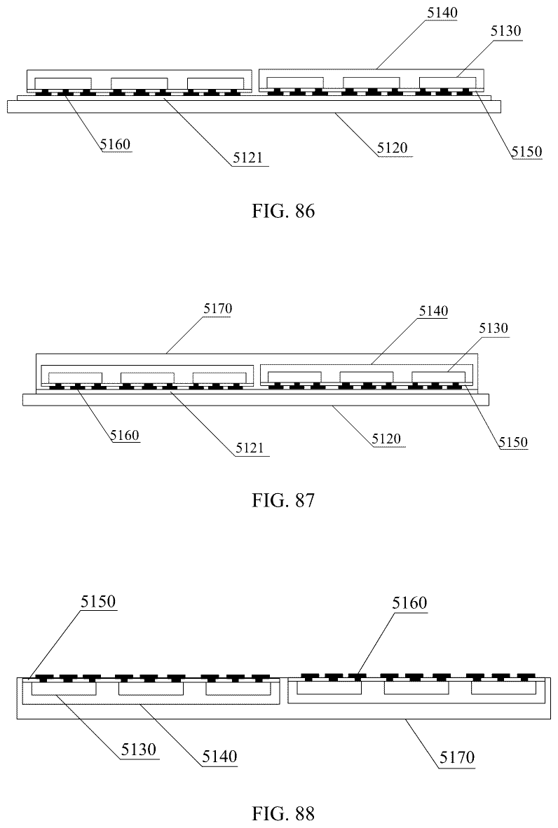

Specifically, as shown in FIG. 85 and FIG. 86, according to the area of the panel carrier 5120, the plurality of groups of first chips 5130 may be cut and fixed on the surface of the panel carrier 5120 in the form of the second array 5B. Using the panel level packaging technology may improve the yield and reduce manufacturing costs. In this embodiment, as shown in FIG. 86, the side on which the high-density interconnection wiring layer is formed may be fixed on the panel carrier 5120 by a second patch adhesive 5121. That is, the first metal interconnection layer 5160 may be attached to second patch adhesive 5121.

In S550, a second plastic encapsulation layer may be formed on a side of the plurality of groups of first chips away from the high-density interconnection wiring layer.

Specifically, as shown in FIG. 87 and FIG. 88, the plurality of groups of first chips may be fixed on the panel carrier 5120 in the form of the second array 5B, and the second plastic encapsulation layer 5170 may be formed on one side of the plurality of groups of first chips away from the high-density interconnection wiring layer. The plastic encapsulation method may be vacuum lamination of film layers or traditional plastic encapsulation process, which is not specifically limited in this embodiment.

In S560, the plurality of groups of first chips may be separated from the panel carrier, and a low-density interconnection wiring layer may be formed on the high-density interconnection wiring layer.

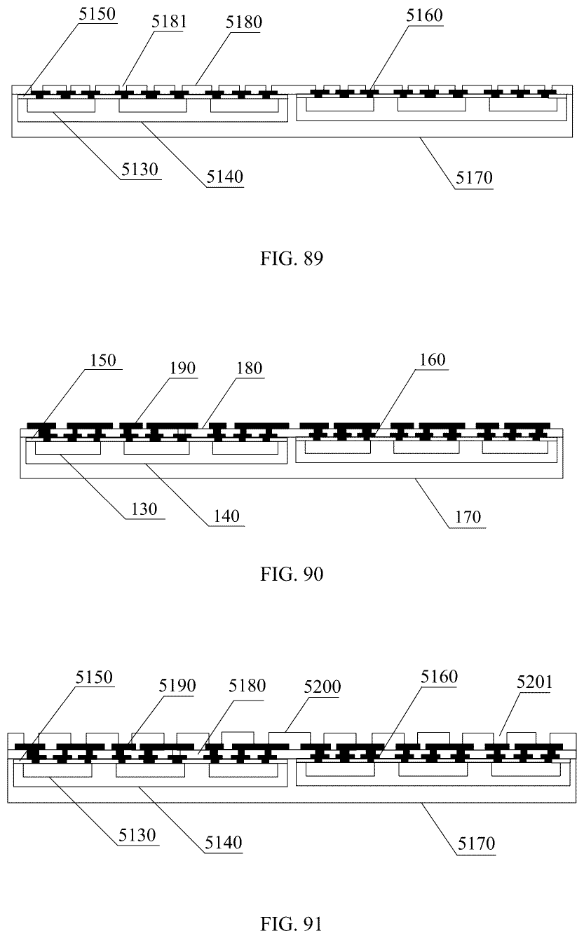

Specifically, as shown in FIG. 88 and FIG. 89, the plurality of groups of first chips 5130 may be separated from the panel carrier 5120. The separation method may be thermal separation, laser separation, ultraviolet light separation, mechanical separation, or other methods. These methods are currently commonly used temporary bonding separation methods. The separation method is not specifically limited in this embodiment, and can be selected according to actual needs.

The low-density interconnection wiring layer on the high-density interconnection wiring layer may be formed by following processes.

First, a second dielectric layer may be formed on the surface of the high-density interconnection wiring layer, and the second dielectric layer may be patterned to form a plurality of second openings.

Specifically, as shown in FIG. 90, the second dielectric layer 5180 may be formed on the first metal interconnection layer 5160. The second dielectric layer 5180 may protect the first metal interconnection layer 5160. The second dielectric layer 180 may be made of a material including a photosensitive dielectric layer (PID) or an Ajinomoto laminated film (ABF), etc., which is not specifically limited in this embodiment. The process in which the second dielectric layer 5180 is coated on the first metal interconnection layer 5160 may be a vacuum lamination or printing process. The present disclosure has no limit on this.

Then, a second metal interconnection layer may be formed on the surface of the patterned second dielectric layer, and the second metal interconnection layer may be patterned to form the low density interconnection wiring layer.

Specifically, as shown in FIG. 91, the second metal interconnection layer 5190 may be deposited on the surface of the patterned second dielectric layer 5180. The deposition method may be electroplating or sputtering. The second metal interconnection layer 5190 may be made of a material including metal titanium or metal copper, which is not specifically limited in this embodiment. The second metal interconnection layer 5190 may be patterned through a photolithography or etching process to form the low-density interconnection wiring layer. The etching process may be wet etching or dry etching, which is not specifically limited in this embodiment.

In one embodiment, as shown in FIG. 85, the first dielectric layer 5150 and the second dielectric layer 5180 may be made of different dielectric materials. The first dielectric layer 5150 may be made of a material including polyimide (PI), polybenzoxazole (PBO), etc. The second dielectric layer 5180 may be made of a material including a photosensitive dielectric layer (PID) or an Ajinomoto laminated film (ABF). The first dielectric layer 5150 may be formed by the wafer-level process, and the second dielectric layer 5180 may be formed by the panel-level process. The preferred dielectric layers may be selected for different processes and the materials of the two dielectric layers may be close to each other. Problems such as poor contact or unrealizable processes may not appear.

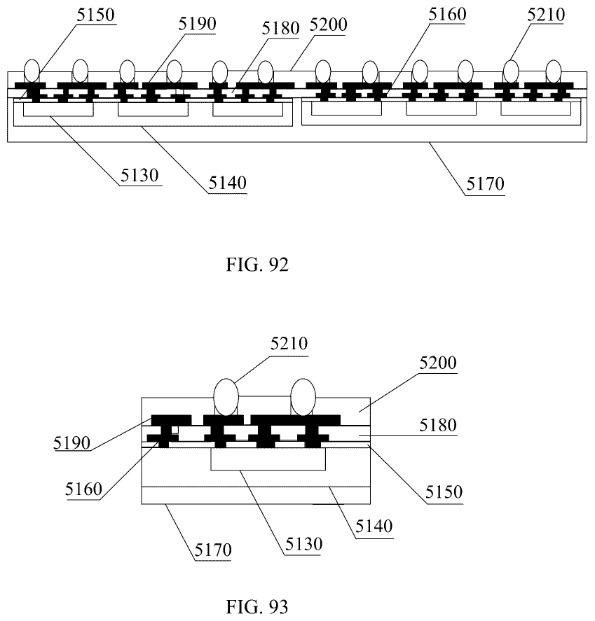

In one embodiment, as shown in FIG. 92, after forming the low-density interconnection wiring layer, the method may further include following processes.

First, a third dielectric layer may be formed on the surface of the patterned second metal interconnection layer.

Specifically, as shown in FIG. 92, the surface of the patterned second metal interconnection layer 5190 may be coated with the third dielectric layer 5200. The third dielectric layer 5200 may be made of a material including photosensitive solder resist (PSR) or the like, which is no specific limitation in this embodiment. The process of coating the second metal interconnection layer 5190 with the third dielectric layer 5200 may be a vacuum lamination process or a printing process, which is not specifically limited in the present disclosure.

Next, the third dielectric layer may be patterned to form a plurality of third openings.

Specifically, as shown in FIG. 92, the third dielectric layer 5200 may be patterned by a photolithography process, to form the plurality of third openings 5201 on the third dielectric layer 5200.

Finally, ball implanting may be performed at the plurality of third openings to form a plurality of solder balls.

Specifically, as shown in FIG. 93, ball implanting may be performed at the plurality of third openings 5201 to form the plurality of solder balls 5210.

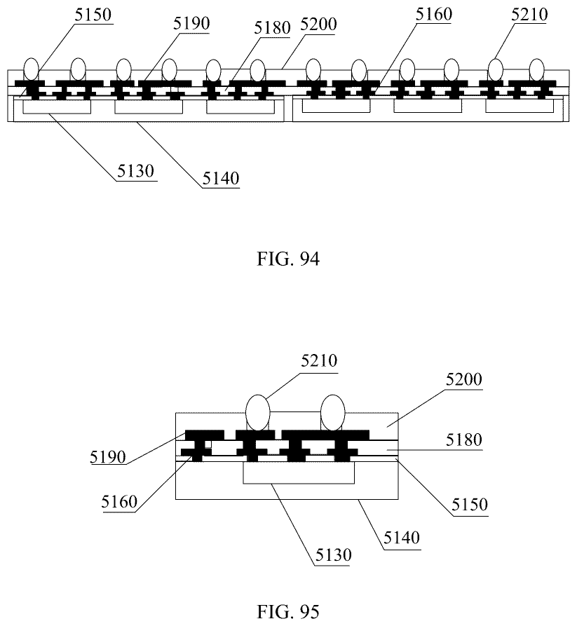

In one embodiment, as shown in FIG. 94, after forming the plurality of solder balls 5210, a side of the second plastic encapsulation layer 5170 away from the plurality of groups of first chips 5130 may be polished to reduce the packaging thickness and form the packaging structure in FIG. 95.

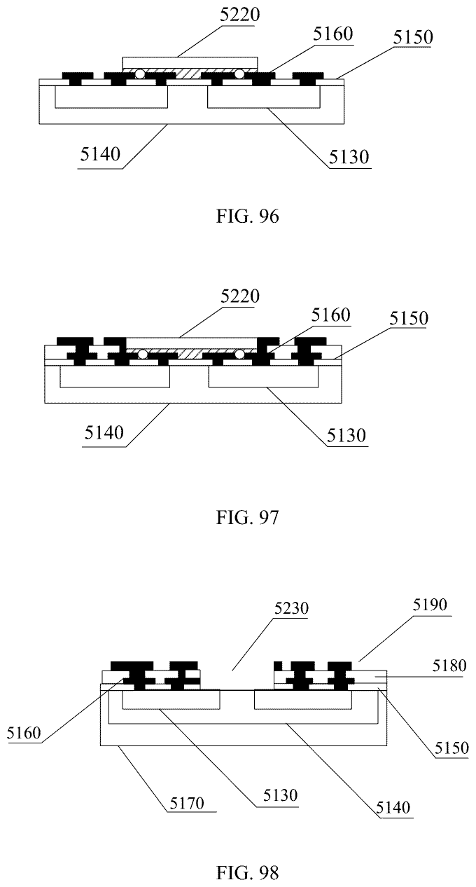

In another embodiment, after forming the second plastic encapsulation layer 5170 on the side of the plurality of groups of first chips 5130 away from the high-density interconnection wiring layer, the side of the second plastic encapsulation layer 5170 away from the plurality of groups of first chips 5130 may be polished to reduce the thickness of the packaging and form the packaging structure in FIG. 96.

In one embodiment, after separating the plurality of groups of first chips 5130 from the wafer carrier 5110 and forming the high-density interconnection wiring layer on the first surfaces of the plurality of groups of first chips 5130, the method may further include: mounting a second chip on the high-density interconnect wiring layer reversely; and forming an intermediate interconnection wiring layer on the high-density interconnection wiring layer.

Specifically, as shown in FIG. 97, the second chip 5220 may be mounted reversely on the high-density interconnect wiring layer, that is, on the first metal interconnection layer 5160. In this embodiment, the second chip 5200 may be a silicon bridge chip. The silicon bridge chip may be mounted reversely on the first metal interconnection layer 5160 and then underfilled. That is, the space between the silicon bridge chip and the first metal interconnection layer 5160 may be filled.

Specifically, as shown in FIG. 97, rewiring may be performed on the high-density interconnection wiring layer, that is, the first metal interconnection layer 5160. Specifically, a dielectric layer and a metal layer may be sequentially formed on the first metal interconnection layer 5160. Then, the metal interconnect layer may be patterned to form an intermediate interconnection wiring layer. After the intermediate interconnection layer is formed, S540 and subsequent packaging steps may be continued. The height of the intermediate interconnection wiring layer may be lower than or same as the height of the second chip 5220. Of course, the height of the intermediate interconnection wiring layer may be preferably configured to be the same as the height of the second chip 5220, such that no processing is required when performing S540 and subsequent packaging steps. When the height of the intermediate interconnection wiring layer is lower than the height of the second chip 5220, a protective layer may be coated on the surface of the intermediate interconnection wiring layer before performing S540 and subsequent packaging steps.

In another embodiment, after separating the plurality of groups of first chips from the panel carrier and forming the low-density interconnection wiring layer on the high-density interconnection wiring layer, the method may further include: patterning the high-density interconnection wiring layer and the low-density interconnection wiring layer to form a target opening area; and mounting a second chip reversely on the target opening area.

Specifically, as shown in FIG. 98, a photolithography process may be used to pattern the high-density interconnection wiring layer and the low-density interconnection wiring second dielectric layer 5180 and the second metal interconnection layer 5190 may be sequentially patterned to form the target opening region 5230.

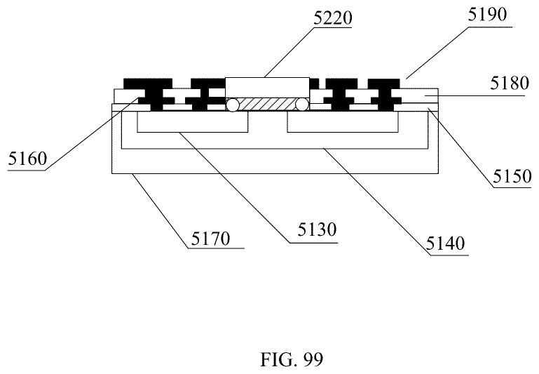

As shown in FIG. 99, the second chip 5220 may be mounted reversely on the target opening area 5230. In this embodiment, the second chip 5220 may be a silicon bridge chip. After the silicon bridge chip is mounted reversely on the target opening area 5230, underfill may be performed. That is, the gap between the silicon bridge chip and the target opening region 5230 may be filled. After the second chip 5220 is mounted reversely on the target opening area 5230, the ball implanting may be performed directly, or may be performed after being covered with a dielectric layer. After the balls are mounted, a cutting process may be performed to form single-group chip package structures.

In the fan-out packaging method and packaging structure provided by the present embodiment, the plurality of groups of first chips may adopt high-density interconnection, which may well meet the requirements of high-density interconnection. The first chips and passive devices may adopt low-density interconnection, which may improve yield and reduce manufacturing cost. By integrating wafer-level fan-out technology and panel-level fan-out technology, different levels of interconnection may be integrated into one package. Compared with the current fan-out wafer-level packaging, the fan-out packaging method of the present embodiment may be able to provide higher interconnection density and meet the requirements of high-performance devices.

It should be noted that, the above embodiment with a 3-layer or 4-layer dielectric layer structure are used as examples to illustrate the present disclosure, and do not limit the scopes of the present disclosure. In various embodiments, the present disclosure may be applied to a variety of layers, which can be adjusted according to actual design needs. The number of interconnection layers used in the wafer-level and panel-level processes can also be adjusted according to actual design needs. For example, when the second interconnection layer also requires high-density interconnection (which cannot be achieved by panel-level processes), wafer-level processes may be used to form two interconnection layers, which are subsequently transferred to the panel-level process.

In one embodiment, as shown in FIG. 77, the middle area of the wafer carrier 5110 may be chip placement areas 5112 and the chip placement areas 5112 may be distributed in the first array A as shown in FIG. 98. The chip placement areas 5112 may be a square structure, and may have a diagonal length equivalent to the diameter of the wafer carrier 5110. Through temporary bonding and wafer-level rerouting, the high-density interconnect wiring layer may be formed in the middle area. The chip placement area 5112 having completed the high-density interconnection may be cut and integrally constructed on the panel carrier 5120 in the form of the second array 5B as shown in FIG. 99.

As shown in FIG. 99, the size of the commonly used panel carrier 5120 may be 510 mm×515 mm. Correspondingly, four chip placement areas 5112 may be disposed at the same time, and the panel level packaging interconnection technology may be used to complete the subsequent process. The production efficiency may be improved and may be able to reach 4 times that of wafer-level packaging technology. When LCD panel technology is used, the production efficiency may be increased by 6-8 times, and the cost may be greatly reduced.

As shown in FIG. 97, since the area of the chip arrangement areas 5112 is smaller than that of the wafer carrier 5110, a certain area loss may occur. Considering that the chips are all rectangular or square in size, the main loss area may be the blank area 5113 in the figure, and the size of its short side may be about 28 mm. For samples with a package size close to or larger than 28 mm, this area may be an invalid area. For samples with a package size close to or smaller than 28 mm, the blank area 5113 may still be used. Therefore, the design of the chip placement areas 5112 may not increase the wafer level cost of packaging. Since the high-density interconnection is mainly used in the fields of high-performance computing and the like, and the packaging in this field is developing in the direction of larger sizes, the present disclosure may significantly reduce the cost.

In the packaging design, an interconnection layer closer to chips may usually have a higher density, while an interconnection layer farther from the chips may have a lower density. The connection line width may show a trend of gradually expanding. Taking advantage of this feature, in the packaging method of the fan-out packaging structure provided by the present disclosure, the fan-out wafer-level packaging technology and the fan-out panel-level packaging technology may be integrated to complete the production of the fan-out packaging. For the interconnection layer closer to the chips, using wafer-level packaging technology may well achieve high-density interconnection requirements. For the interconnection layer farther away from the chips, using panel-level packaging technology may improve yield and reduce manufacturing costs.

Another embodiment of the present disclosure also provides another fan-out packaging structure 500. As shown in FIG. 93, in one embodiment, the fan-out packaging structure 500 may include a group of first chips 5130, a plastic encapsulation layer 5140, a high-density interconnection wiring layer (not shown in the figure), and a low-density interconnection wiring layer (not shown in the figure).

The plastic encapsulation layer 5140 may wrap the group of first chips 5130, and the high-density interconnection wiring layer may be sandwiched between the plastic encapsulation layer 5140 and the low-density interconnection wiring layer.

In one embodiment, as shown in FIG. 93, the high-density interconnection wiring layer may include a first dielectric layer 5150 disposed on the group of first chips 5130, and a first metal interconnection layer 5160 on the first dielectric layer 5150.

The first dielectric layer 5150 may be made of a material including polyimide (PI), or polybenzoxazole (PBO), etc., and may be formed by a coating method usually including wafer spin coating, which is not specifically limited in this embodiment. The first dielectric layer 1150 may protect the plurality of groups of the first chips 5130. The material and coating process of the first dielectric layer 5150 are not specifically limited in this embodiment, and can be selected according to actual needs.

The first metal interconnection layer 5160 may be deposited on the first dielectric layer 5140 by a process including electroplating, sputtering, thermal evaporation, plasma-enhanced chemical vapor deposition, low-pressure chemical vapor deposition, atmospheric pressure chemical vapor deposition, or electron cyclotron resonance chemical vapor deposition. The first metal interconnection layer 5160 may be made of a metal material including titanium or copper. The deposition method and metal material of the first metal interconnection layer 5160 are not specifically limited in this embodiment.

As shown in FIG. 93, the low-density interconnection wiring layer may include a second dielectric layer 5180 disposed on the first metal interconnection layer 5160, and a second metal interconnection layer 1190 on the second dielectric layer 5180.

The second dielectric layer 5180 may be made of a photosensitive dielectric layer (PID) or an Ajinomoto laminated film (ABF), etc., which is not specifically limited in this embodiment. The process in which the second dielectric layer 5180 covers the surface of the first metal interconnection layer 5160 may be a vacuum lamination process or a printing process, which is not specifically limited in this embodiment.

The second metal interconnection layer 5190 may be deposited on the second dielectric layer 5180 by a process including electroplating, sputtering, thermal evaporation, plasma enhanced chemical vapor deposition, low pressure chemical vapor deposition, atmospheric pressure chemical vapor deposition, or electron cyclotron resonance chemical vapor deposition. The second metal interconnection layer 5190 may be made of a metal material including titanium or copper. The deposition method and metal material of the second metal interconnection layer 5190 are not specifically limited in this embodiment.

The first dielectric layer 5150 and the second dielectric layer 5180 may be made of different dielectric materials. The first dielectric layer 5150 may be made of a material including polyimide (PI), polybenzoxazole (PBO), etc. The second dielectric layer 1180 may be made of a material including a photosensitive dielectric layer (PID) or an Ajinomoto laminated film (ABF). The first dielectric layer 5150 may be made by the wafer-level process, and the second dielectric layer 1180 may be made by the panel-level process. The preferred dielectric layers may be selected for different processes and the materials of the two dielectric layers may be close to each other. Problems such as poor contact or unrealizable processes may not appear.

In one embodiment, as shown in FIG. 93, the packaging structure 500 may further include a third dielectric layer 5200 on the second metal interconnect layer 5190 and a plurality of solder balls 5210 on the third dielectric layer 5200.

The third dielectric layer 5200 may be made of a material including photosensitive solder resist (PSR), etc., which is not specifically limited in this embodiment. The process in which the third dielectric layer 5200 covers the second metal interconnection layer 5190 may be a vacuum lamination process or a printing process, which is not specifically limited in this embodiment.

In one embodiment, a side of the second plastic encapsulation layer 5170 away from the plurality of groups of first chips 5130 may be polished to reduce the packaging thickness and form the packaging structure in FIG. 95.

In another embodiment, after forming the second plastic encapsulation layer 5170 on the side of the plurality of groups of first chips 5130 away from the high-density interconnection wiring layer, the side of the second plastic encapsulation layer 5170 away from the plurality of groups of first chips 5130 may be polished to reduce the thickness of the packaging and form the packaging structure in FIG. 96.

In one embodiment, after separating the plurality of groups of first chips 5130 from the wafer carrier 5110 and forming the high-density interconnection wiring layer on the first surfaces of the plurality of groups of first chips 5130, the method may further include: mounting a second chip on the high-density interconnect wiring layer reversely; and forming an intermediate interconnection wiring layer on the high-density interconnection wiring layer.

Specifically, as shown in FIG. 97, the second chip 5220 may be mounted reversely on the high-density interconnect wiring layer, that is, on the first metal interconnection layer 5160. In this embodiment, the second chip 5200 may be a silicon bridge chip. The silicon bridge chip may be mounted reversely on the first metal interconnection layer 5160 and then underfilled. That is, the space between the silicon bridge chip and the first metal interconnection layer 5160 may be filled.

Specifically, as shown in FIG. 97, rewiring may be performed on the high-density interconnection wiring layer, that is, the first metal interconnection layer 5160. Specifically, a dielectric layer and a metal layer may be sequentially formed on the first metal interconnection layer 5160. Then, the metal interconnect layer may be patterned to form an intermediate interconnection wiring layer. After the intermediate interconnection layer is formed, S540 and subsequent packaging steps may be continued. The height of the intermediate interconnection wiring layer may be lower than or same as the height of the second chip 5220. Of course, the height of the intermediate interconnection wiring layer may be preferably configured to be the same as the height of the second chip 5220, such that no processing is required when performing S540 and subsequent packaging steps. When the height of the intermediate interconnection wiring layer is lower than the height of the second chip 5220, a protective layer may be coated on the surface of the intermediate interconnection wiring layer before performing S540 and subsequent packaging steps.

In another embodiment, after separating the plurality of groups of first chips from the panel carrier and forming the low-density interconnection wiring layer on the high-density interconnection wiring layer, the method may further include: patterning the high-density interconnection wiring layer and the low-density interconnection wiring layer to form a target opening area; and mounting a second chip reversely on the target opening area.

Specifically, as shown in FIG. 98, a photolithography process may be used to pattern the high-density interconnection wiring layer and the low-density interconnection wiring second dielectric layer 5180 and the second metal interconnection layer 5190 may be sequentially patterned to form the target opening region 5230.

As shown in FIG. 99, the second chip 5220 may be mounted reversely on the target opening area 5230. In this embodiment, the second chip 5220 may be a silicon bridge chip. After the silicon bridge chip is mounted reversely on the target opening area 5230, underfill may be performed. That is, the gap between the silicon bridge chip and the target opening region 5230 may be filled. After the second chip 5220 is mounted reversely on the target opening area 5230, the ball implanting may be performed directly, or may be performed after being covered with a dielectric layer. After the balls are mounted, a cutting process may be performed to form single-group chip package structures.

In the fan-out packaging method and packaging structure provided by the present embodiment, the plurality of groups of first chips may adopt high-density interconnection, which may well meet the requirements of high-density interconnection. The first chips and passive devices may adopt low-density interconnection, which may improve yield and reduce manufacturing cost. By integrating wafer-level fan-out technology and panel-level fan-out technology, different levels of interconnection may be integrated into one package. Compared with the current fan-out wafer-level packaging, the fan-out packaging method of the present embodiment may be able to provide higher interconnection density and meet the requirements of high-performance devices.

The embodiments disclosed herein are exemplary only. Other applications, advantages, alternations, modifications, or equivalents to the disclosed embodiments are obvious to those skilled in the art and are intended to be encompassed within the scope of the present disclosure.

What is claimed is:

1. A fan-out packaging method, comprising:
providing a wafer carrier, a panel carrier, and a plurality of groups of first chips;
fixing first surfaces of the plurality of groups of first chips on a surface of the wafer carrier in a form of a first array;
forming a first plastic encapsulation layer on second surfaces of the plurality of groups of first chips;
separating the plurality of groups of first chips from the wafer carrier;
forming a high-density interconnection wiring layer on the first surfaces of the plurality of groups of first chips;
cutting the plurality of groups of first chips;
fixing one side of the plurality of groups of first chips with the high-density interconnection wiring layer on a surface of the panel carrier;
forming a second plastic encapsulation layer on another side of the plurality of groups of first chips away from the high-density interconnection wiring layer;
separating the plurality of groups of first chips from the panel carrier; and
forming a low-density interconnection wiring layer on the high-density interconnection wiring layer.

2. The method according to claim 1, wherein:
the first surfaces of the plurality of groups of first chips are provided with a plurality of conductive bumps; and
before forming the high-density interconnection wiring layer on the first surfaces of the plurality of groups of first chips, the method further includes: separating the plurality of groups of first chips from the wafer carrier, and grinding the first surfaces of the plurality of groups of first chips to expose the plurality of conductive bumps.

3. The method according to claim 1, wherein forming the high-density interconnection wiring layer on the first surfaces of the plurality of groups of first chips includes:
forming a first dielectric layer on the first plastic encapsulation layer and the plurality of groups of first chips;
patterning the first dielectric layer to form a plurality of first openings; and
forming a first metal interconnection layer on a surface of the patterned first dielectric layer, and patterning the first metal interconnection layer to form the high-density interconnection wiring layer.

4. The method according to claim 3, wherein forming the low-density interconnection wiring layer on the high-density interconnection wiring layer includes:
forming a second dielectric layer is formed on the surface of the high-density interconnection wiring layer;
patterning the second dielectric layer to form a plurality of second openings;
forming a second metal interconnection layer on a surface of the patterned second dielectric layer; and
patterning the second metal interconnection layer to form the low-density interconnection wiring layer.

5. The method according to claim 4, wherein the first dielectric layer and the second dielectric layer are made of different dielectric materials.

6. The method according to claim 4, after forming the low-density interconnection wiring layer, further comprising:
forming a third dielectric layer on a surface of the patterned second metal interconnection layer;
patterning the third dielectric layer to form a plurality of third openings;
performing ball implantation on the plurality of third openings to form a plurality of solder balls; and
cutting the plurality of groups of first chips to form single-group chip packaging structures.

7. The method according to claim 6, wherein:
after forming the plurality of solder balls, a side of the second plastic encapsulation layer away from the plurality of groups of first chips is polished; or
after forming the second plastic encapsulation layer on the side of the plurality of groups of first chips away from the high-density interconnection wiring layer, a side of the second plastic encapsulation layer away from the plurality of groups of first chips is polished.

8. The method according to claim 1, wherein:
each group of first chips includes one or more first chips.

9. The method according to claim 1, wherein:
the first surfaces are front surfaces of the plurality of groups of first chips and the second surfaces are back surfaces of the plurality of groups first chips; or
the first surfaces are back surfaces of the plurality of groups of first chips and the second surfaces are front surfaces of the plurality of groups of first chips.

10. The method according to claim 1, wherein:
the first surfaces of the plurality of groups of first chips are fixed on the surface of the wafer carrier by a hybrid bonding structure.

11. The method according to claim 10, wherein:
the hybrid bonding structure includes first passivation layers and first metal pads disposed on the first surfaces of the plurality of groups of first chips, and second passivation layers and second metal pads disposed on the side of the wafer carrier facing the plurality of groups of the first chips, wherein:
the first passivation layers and the second passivation layers are hybrid-bonded and connected, and the first metal pads and the second metal pads are hybrid-bonded and connected.

12. The method according to claim 1, after cutting the plurality of groups of first chips and fixing one side of the plurality of groups of first chips with the high-density interconnection wiring layer on the surface of the panel carrier, further comprising:
fixing a plurality of second chips and a plurality of passive devices on the surface of the panel carriers, wherein:
when forming the second plastic encapsulation layer, the second plastic encapsulation layer is also formed on surfaces of the plurality of second chips and the plurality of passive devices; and
when separating the plurality of groups of first chips from the panel carrier, the plurality of second chips and the plurality of passive devices are also separated from the panel carrier.

13. The method according to claim 12, wherein:
the passive devices include resistors, capacitors, inductors, converters, faders, matching networks, resonators, filters, mixers, or switches.

14. The method according to claim 1, wherein:
each group of first chips includes at least two different types of chips.

15. The method according to claim 1, after forming the high-density interconnection wiring layer on the first surfaces of the plurality of groups of first chips, further comprising:
reversely mounting the plurality of groups of second chips on the high-density interconnection wiring layer; and
forming an intermediate interconnection wiring layer on the high-density interconnection wiring layer.

16. The method according to claim 1, wherein after forming the low-density interconnection wiring layer on the high-density interconnection wiring layer, further comprising:
patterning the low-density interconnection wiring layer and the high-density interconnection wiring layer to form a target opening area; and
reversely mounting second chips at the target opening area.

17. A fan-out packaging structure, comprising:
a group of first chips;
a high-density interconnection wiring layer;
a low-density interconnection wiring layer;
a first plastic encapsulation layer; and
a second plastic encapsulation layer,
wherein:
the high-density interconnection wiring layer is disposed on the first encapsulation layer and first surfaces of the group of first chips;
the low-density interconnection wiring layer is disposed on the high-density interconnection wiring layer;
the first plastic encapsulation layer and the second encapsulation layer wrap the group of first chips.

18. The structure according to claim 17, wherein:
the high-density interconnection wiring layer includes a first dielectric layer on the first plastic encapsulation layer and the group of first chips; and a first metal interconnection layer on the first dielectric layer.

19. The structure according to claim 18, wherein:
the low-density interconnection wiring layer includes a second dielectric layer on the first metal interconnection layer and the group of first chips, and a second metal interconnection layer on the second dielectric layer.

20. The structure according to claim 19, further including a third dielectric layer on the second metal interconnection layer and solder balls on the third dielectric layer.
